(19) United States
(12) Patent Application Publication
(10) Pub. No.: US 2024/0332410 A1
(43) Pub. Date: Oct. 3, 2024

(54) SEMICONDUCTOR DEVICE, AND PRODUCTION METHOD FOR SEMICONDUCTOR DEVICE

(71) Applicant: SUMITOMO ELECTRIC DEVICE INNOVATIONS, INC., Kanagawa (JP)

(72) Inventor: Yuya TSUTSUMI, Kanagawa (JP)

(21) Appl. No.: 18/608,013

(22) Filed: Mar. 18, 2024

(30) Foreign Application Priority Data
Mar. 27, 2023 (JP) 2023-050154

(51) Int. Cl. H01L 29/778; H01L 21/311; H01L 29/20; H01L 29/66

(52) U.S. Cl. CPC H01L 29/7786; H01L 21/31116; H01L 29/2003; H01L 29/66462

(57) ABSTRACT

A semiconductor device includes a substrate, a first nitride semiconductor layer, a first metal layer, a b second metal layer, a third metal layer, and a fourth metal layer. The substrate, first nitride semiconductor layer, and first metal layer have a through-hole that penetrates the substrate, first nitride semiconductor layer, and first metal layer and to which the second metal layer is exposed. The first metal layer makes an Ohmic contact with the first nitride semiconductor layer. Resistance of the second metal layer to etching using a reactive gas is higher than resistance of the first metal layer to etching using the reactive gas. Resistivity of the third metal layer is lower than resistivity of the first metal layer and resistivity of the second metal layer. The fourth metal layer is on an inner surface of the through-hole and is in direct contact with the second metal layer.

### CROSS-REFERENCE TO RELATED APPLICATIONS

This application is based on and claims priority to Japanese Patent Application No. 2023-050154, filed on Mar. 27, 2023, the entire contents of which are incorporated herein by reference.

### TECHNICAL FIELD

The present disclosure relates to semiconductor devices, and production methods of semiconductor devices.

### BACKGROUND

Known semiconductor devices include a substrate; a semiconductor layer on the substrate; a metal layer on the semiconductor layer, the metal layer serving as an etching stopper; a through-hole penetrating the substrate and the semiconductor layer and reaching the etching stopper; and a backside electrode on a lower surface of the substrate and connected via the through-hole to the etching stopper. See, for example, Japanese Patent Publication No. 2019-145546 and Japanese Patent Publication No. 2020-17647.

### SUMMARY

A semiconductor device of the present disclosure includes: a substrate; a first nitride semiconductor layer on the substrate; a first metal layer on the first nitride semiconductor layer; a second metal layer on the first metal layer; a third metal layer on the second metal layer; and a fourth metal layer. The substrate, the first nitride semiconductor layer, and the first metal layer have a through-hole that penetrates the substrate, the first nitride semiconductor layer, and the first metal layer and to which the second metal layer is exposed. The first metal layer makes an Ohmic contact b with the first nitride semiconductor layer. Resistance of the second metal layer to etching using a reactive gas is higher than resistance of the first metal layer to etching using the reactive gas. Resistivity of the third metal layer is lower than resistivity of the first metal layer and resistivity of the second metal layer. The fourth metal layer is on an inner surface of the through-hole and is in direct contact with the second metal layer.

### BRIEF DESCRIPTION OF THE DRAWINGS

FIG. 1 is a diagram illustrating a layout of a gate electrode, a source wire, and a drain wire in a semiconductor device according to a first embodiment;

FIG. 2 is a cross-sectional diagram illustrating the semiconductor device according to the first embodiment;

FIG. 3 is a cross-sectional diagram illustrating a production method for the semiconductor device according to the first embodiment (part 1);

FIG. 4 is a cross-sectional diagram illustrating the production method for the semiconductor device according to the first embodiment (part 2);

FIG. 5 is a cross-sectional diagram illustrating the production method for the semiconductor device according to the first embodiment (part 3);

FIG. 6 is a cross-sectional diagram illustrating the production method for the semiconductor device according to the first embodiment (part 4);

FIG. 7 is a cross-sectional diagram illustrating the production method for the semiconductor device according to the first embodiment (part 5);

FIG. 8 is a cross-sectional diagram illustrating the production method for the semiconductor device according to the first embodiment (part 6);

FIG. 9 is a cross-sectional diagram illustrating the production method for the semiconductor device according to the first embodiment (part 7);

FIG. 10 is a cross-sectional diagram illustrating the production method for the semiconductor device according to the first embodiment (part 8);

FIG. 11 is a cross-sectional diagram illustrating the production method for the semiconductor device according to the first embodiment (part 9);

FIG. 12 is a cross-sectional diagram illustrating the production method for the semiconductor device according to the first embodiment (part 10);

FIG. 13 is a cross-sectional diagram illustrating the production method for the semiconductor device according to the first embodiment (part 11);

FIG. 14 is a cross-sectional diagram illustrating a semiconductor device according to a referential example;

FIG. 15 is a cross-sectional diagram illustrating a semiconductor device according to a second embodiment;

FIG. 16 is a cross-sectional diagram illustrating a semiconductor device according to a third embodiment;

FIG. 17 is a cross-sectional diagram illustrating a production method for the semiconductor device according to the third embodiment (part 1);

FIG. 18 is a cross-sectional diagram illustrating the production method for the semiconductor device according to the third embodiment (part 2);

FIG. 19 is a cross-sectional diagram illustrating the production method for the semiconductor device according to the third embodiment (part 3);

FIG. 20 is a cross-sectional diagram illustrating the production method for the semiconductor device according to the third embodiment (part 4);

FIG. 21 is a cross-sectional diagram illustrating the production method for the semiconductor device according to the third embodiment (part 5);

FIG. 22 is a cross-sectional diagram illustrating the production method for the semiconductor device according to the third embodiment (part 6);

FIG. 23 is a cross-sectional diagram illustrating a semiconductor device according to a fourth embodiment;

FIG. 24 is a cross-sectional diagram illustrating a semiconductor device according to a fifth embodiment;

FIG. 25 is a cross-sectional diagram illustrating a production method for the semiconductor device according to the fifth embodiment (part 1);

FIG. 26 is a cross-sectional diagram illustrating the production method for the semiconductor device according to the fifth embodiment (part 2);

FIG. 27 is a cross-sectional diagram illustrating the production method for the semiconductor device according to the fifth embodiment (part 3);

FIG. 28 is a cross-sectional diagram of a semiconductor device according to a sixth embodiment;

FIG. 29 is a cross-sectional diagram illustrating a production method for the semiconductor device according to the sixth embodiment (part 1);

FIG. 30 is a cross-sectional diagram illustrating the production method for the semiconductor device according to the sixth embodiment (part 2);

FIG. 31 is a cross-sectional diagram illustrating the production method for the semiconductor device according to the sixth embodiment (part 3);

FIG. 32 is a cross-sectional diagram illustrating the production method for the semiconductor device according to the sixth embodiment (part 4); and

FIG. 33 is a cross-sectional diagram illustrating the production method for the semiconductor device according to the sixth embodiment (part 5).

### DETAILED DESCRIPTION

In existing semiconductor devices, a metal layer, formed as an etching stopper, and a semiconductor layer cannot make an Ohmic contact with each other. Thus, the existing semiconductor devices are provided with a metal layer for ensuring the Ohmic contact. Formation of more through-holes is an obstacle to downsizing of the semiconductor device.

It is an object of the present disclosure to provide: a semiconductor device that can be downsized; and a production method for the semiconductor device.

According to the present disclosure, it is possible to downsize a semiconductor device.

### Description of Embodiments of the Present Disclosure

First, embodiments of the present disclosure will be described below.

[1] A semiconductor device according to an embodiment of the present disclosure includes: a substrate; a first nitride semiconductor layer on the substrate; a first metal layer on the first nitride semiconductor layer; a second metal layer on the first metal layer; a third metal layer on the second metal layer; and a fourth metal layer, in which the substrate, the first nitride semiconductor layer, and the first metal layer have a through-hole that penetrates the substrate, the first nitride semiconductor layer, and the first metal layer and to which the second metal layer is exposed, the first metal layer makes an Ohmic contact with the first nitride semiconductor layer, resistance of the second metal layer to etching using a reactive gas is higher than resistance of the first metal layer to etching using the reactive gas, resistivity of the third metal layer is lower than resistivity of the first metal layer and resistivity of the second metal layer, and the fourth metal layer is on an inner surface of the through-hole and is in direct contact with the second metal layer.

The second metal layer is provided between the first metal layer and the third metal layer, and the resistance of the second metal layer to etching using the reactive gas is higher than the resistance of the first metal layer to etching using the reactive gas. With this configuration, the second metal layer can be used as an etching stopper during formation of the through-hole. Thus, in a plan view, a region for the second metal layer does not need to be provided apart from a region for the first metal layer. Therefore, this configuration can be downsized compared to a configuration in which the region for the second metal layer is provided apart from the region for the first metal layer.

[2] In [1], the reactive gas may include chlorine or fluorine. When the reactive gas includes chlorine, the first nitride semiconductor layer is readily etched. When the reactive gas includes fluorine, the substrate and the first nitride semiconductor layer are readily etched.

[3] In [1] or [2], the substrate may be a silicon carbide substrate. In this case, the first nitride semiconductor layer readily has favorable b crystallinity.

[4] In any one of [1] to [3], the first nitride semiconductor layer may include: a second nitride semiconductor layer including a recess in a surface of the second nitride semiconductor layer, the surface facing the first metal layer; and a third nitride semiconductor layer in the recess, the third nitride semiconductor layer having a carrier density higher than a carrier density of the second nitride semiconductor layer, and the first metal layer may make an Ohmic contact with the third nitride semiconductor layer. In this case, contact resistance between the first metal layer and the first nitride semiconductor layer can be reduced.

[5] In any one of [1] to [4], the second metal layer may include a nickel layer exposed to the through-hole. In this case, it is possible to readily obtain excellent resistance to etching using the reactive gas including chlorine or fluorine.

[6] In [5], the nickel layer may be an electrolytic nickel plating layer, and the semiconductor device may further include a plating base layer between the first metal layer and the electrolytic nickel plating layer. In this case, the second metal layer having a large thickness can be readily formed through electrolytic plating using the plating base layer as an electric power supply path.

[7] In [5], the nickel layer may be an electroless nickel plating layer, and the semiconductor device may further include a catalytic layer between the first metal layer and the electroless nickel plating layer, and an adhesion layer between the first metal layer and the catalytic layer and in direct contact with the first metal layer and the catalytic layer. In this case, the second metal layer having a large thickness can be readily formed through electroless plating.

[8] In any one of [1] to [7], the first metal layer may include a titanium layer, a tantalum layer, a gold layer, or an aluminum layer, the titanium layer, the tantalum layer, the gold layer, or the aluminum layer being in direct contact with the first nitride semiconductor layer. In this case, the first metal layer readily makes an Ohmic contact with the first nitride semiconductor layer.

[9] In [4], the second metal layer may include an electroless nickel plating layer exposed to the through-hole, and the first metal layer may include a catalytic layer between the third nitride semiconductor layer and the electroless nickel plating layer, and an adhesion layer between the third nitride semiconductor layer and the catalytic layer and in direct contact with the third nitride semiconductor layer and the catalytic layer. In this case, the second metal layer having a large thickness can be formed through electroless plating using the first metal layer.

[10] A semiconductor device according to another embodiment of the present disclosure includes: a silicon carbide substrate; a first nitride semiconductor layer on the silicon carbide substrate; a first metal layer on the first nitride semiconductor layer, the first metal layer including a titanium layer, a tantalum layer, a gold layer, or an aluminum layer; a nickel plating layer on the first metal layer; a first gold layer on the nickel plating layer; and a second gold layer, in which: the first nitride semiconductor layer includes a second nitride semiconductor layer including a recess in a b surface of the second nitride semiconductor layer, the surface facing the first metal layer, and a third nitride semiconductor layer in the recess, the third nitride semiconductor layer having a carrier density higher than a carrier density of the second nitride semiconductor layer; the silicon carbide substrate, the first nitride semiconductor layer, and the first metal layer have a through-hole that penetrates the silicon carbide substrate, the first nitride semiconductor layer, and the first metal layer and to which the nickel plating layer is exposed; the first metal layer makes an Ohmic contact with the third nitride semiconductor layer; and the second gold layer is on an inner surface of the through-hole and in direct contact with the nickel plating layer.

The nickel plating layer can be used as an etching stopper during formation of the through-hole. Thus, in a plan view, a region for the nickel plating layer does not need to be provided apart from a region for the first metal layer. Therefore, this configuration can be downsized compared to a configuration in which the region for the nickel plating layer is provided apart from the region for the first metal layer.

[11] A production method for a semiconductor device according to still another embodiment of the present disclosure includes: forming a first nitride semiconductor layer on a substrate; forming a first metal layer on the first nitride semiconductor layer, the first metal layer making an Ohmic contact with the first nitride semiconductor layer; forming a second metal layer on the first metal layer, resistance of the second metal layer to etching using a reactive gas being higher than resistance of the first metal layer to etching using the reactive gas; forming a third metal layer on the second b metal layer, resistivity of the third metal layer being lower than resistivity of the first metal layer and the second metal layer; forming a through-hole through the substrate, the first nitride semiconductor layer, and the first metal layer by etching using the reactive gas, where the through-hole penetrates the substrate, the first nitride semiconductor layer, and the first metal layer, and the second metal layer is exposed to the through-hole; and forming a fourth metal layer on an inner surface of the through-hole, the fourth metal layer being in direct contact with the second metal layer. The second metal layer can be used as an etching stopper during formation of the through-hole. Thus, in a plan view, a region for the second metal layer does not need to be provided apart from a region for the first metal layer. Therefore, this configuration can be downsized compared to a configuration in which the region for the second metal layer is provided apart from the region for the first metal layer.

### Details of Embodiments of Present Disclosure

Hereinafter, embodiments of the present disclosure will be described in detail, but the present disclosure is not limited to the described embodiments. In the present specification and the drawings, constituent elements having substantially the same functional configuration are designated by the same reference numerals, and a redundant description thereof may be omitted. In the following description, an XYZ orthogonal coordinate system is used, but this coordinate system is merely defined for the sake of convenience of description, and does not limit an orientation of the semiconductor device in any way. Further, when viewed from an arbitrary point, a +Z-side may be referred to as upward, upper b side, or upper, and a −Z-side may be referred to as downward, lower side, or lower.

### First Embodiment

A first embodiment will be described. The first embodiment relates to a semiconductor device including a GaN-based high electron mobility transistor (HEMT).

### [Configuration of Semiconductor Device]

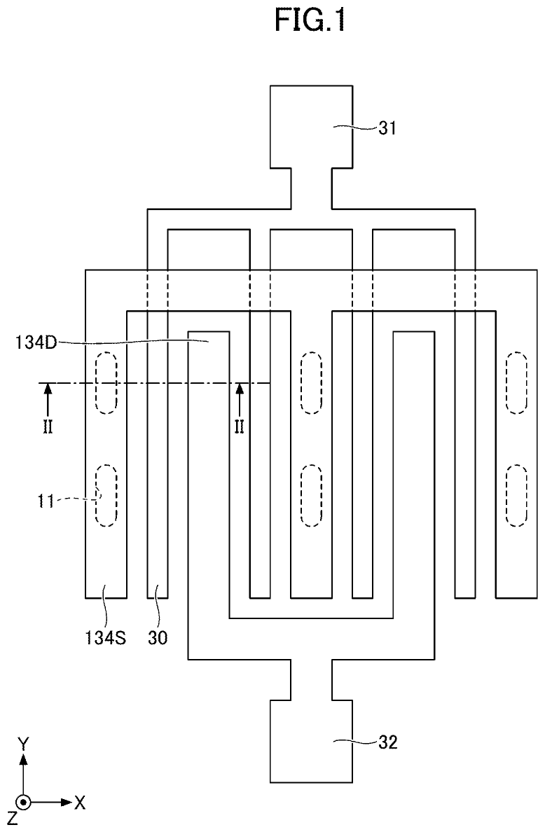

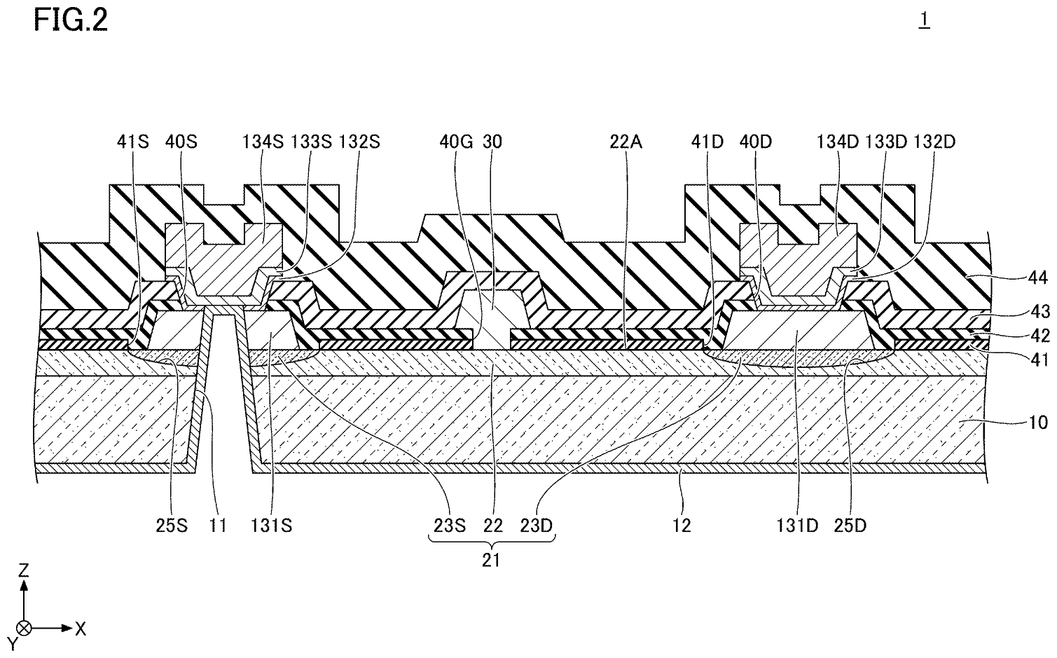

A configuration of the semiconductor device according to the first embodiment will be described. FIG. 1 is a diagram illustrating a layout of a gate electrode, a source wire, and a drain wire in the semiconductor device according to the first embodiment. FIG. 2 is a cross-sectional diagram illustrating the semiconductor device according to the first embodiment. FIG. 2 corresponds to a cross-sectional diagram as taken along line II-II in FIG. 1.

As illustrated in FIG. 1 and FIG. 2, the semiconductor device 1 according to the first embodiment mainly includes a substrate 10, a semiconductor layer 21, a gate electrode 30, a source electrode 131S, a drain electrode 131D, an etching stopper 133S, an etching stopper 133D, a source wire 134S, a drain wire 134D, and a backside electrode 12. The semiconductor layer 21 includes a semiconductor layer 22, a semiconductor layer 23S, and a semiconductor layer 23D. The semiconductor layer 21 is an example of the first nitride semiconductor layer.

The substrate 10 is, for example, a silicon carbide (SiC) substrate. The semiconductor layer 22 is provided on the substrate 10. The semiconductor layer 22 is a nitride semiconductor layer including, for example, gallium (Ga). The nitride semiconductor layer forms a part of a high electron mobility transistor, such as an electron transit layer (channel layer), an electron supply layer (barrier layer), or the like. The semiconductor layer 22 is an example of the second nitride semiconductor layer.

In an upper surface 22A of the semiconductor layer 22, a plurality of recesses 25S and a plurality of recesses 25D are formed. The recesses 25S and 25D extend in parallel to a Y-axis direction, and are alternately provided in an X-axis direction. For example, the recesses 25S and 25D reach the electron transit layer (channel layer). Bottom surfaces of the recesses 25S and 25D may be in the electron transit layer.

The semiconductor device 1 includes an insulating film 41. The insulating film 41 covers the upper surface 22A of the semiconductor layer 22. For example, the insulating film 41 is a nitride film, such as a silicon nitride (SiN) film or the like. A plurality of openings 41S and a plurality of openings 41D are formed in the insulating film 41. The openings 41S and 41D extend in parallel to the Y-axis direction. The opening 41S is continuous with the recess 25S, and the opening 41D is continuous with the recess 25D.

The semiconductor layer 23S is provided in the recess 25S, and the semiconductor layer 23D is provided in the recess 25D. A part of the semiconductor layer 23S may be in the opening 41S, and a part of the semiconductor layer 23D may be in the opening 41D. For example, the semiconductor layers 23S and 23D are a gallium nitride (GaN) layer of an n-type conductivity. The semiconductor layers 23S and 23D are a re-grown layer. A carrier density of the semiconductor layers 23S and 23D is higher than a carrier density of the semiconductor layer 22. The semiconductor layers 23S and 23D include n-type impurities, for example, at a concentration of 1.0×10¹⁸ cm⁻³ or more. The semiconductor layer 23S and the semiconductor layer 23D are, for example, a degenerate semiconductor layer. The n-type impurities are, for example, silicon (Si) or germanium (Ge). The semiconductor layer 23S is an example of the third nitride semiconductor layer.

The source electrode 131S and the drain electrode 131D extend in parallel to the Y-axis direction. In a plan view, the source electrode 131S is provided on the semiconductor layer 23S in the opening 41S. The source electrode 131S includes, for example, an aluminum (Al) layer in direct contact with the semiconductor layer 23S. In a plan view, the drain electrode 131D is provided on the semiconductor layer 23D in the opening 41D. The drain electrode 131D includes, for example, an Al layer in direct contact with the semiconductor layer 23D. The source electrode 131S makes an Ohmic contact with the semiconductor layer 23S, and the drain electrode 131D makes an Ohmic contact with the semiconductor layer 23D. The source electrode 131S is an example of the first metal layer. The upper surface 22A of the semiconductor layer 22 faces the source electrode 131S and the drain electrode 131D.

The semiconductor device 1 includes an insulating film 42. The insulating film 42 covers the insulating film 41, the semiconductor layer 23S, the semiconductor layer 23D, the source electrode 131S, and the drain electrode 131D. For example, the insulating film 42 is a nitride film, such as an SiN film or the like. A plurality of openings 40G are formed in a laminate of the insulating films 41 and 42. The opening 40G extends in parallel to the Y-axis direction. The opening 40G is provided between the opening 41S and the opening 41D that are next to each other in the X-axis direction.

The gate electrode 30 extends in parallel to the Y-axis direction. The gate electrode 30 covers the opening 40G and makes a Schottky contact with the semiconductor layer 21 through the opening 40G. The gate electrode 30 includes, for example, a nickel (Ni) layer and a gold (Au) layer that are laminated upward in this order. As illustrated in FIG. 1, a plurality of the gate electrodes 30 are connected to a gate common connection portion 31.

The semiconductor device 1 includes an insulating film 43. The insulating film 43 covers the gate electrode 30 and the insulating film 42. For example, the insulating film 43 is a nitride film, such as an SiN film or the like. A plurality of openings 40S and a plurality of openings 40D are formed in a laminate of the insulating films 42 and 43. The openings 40S and 40D extend in parallel to the Y-axis direction. The opening 40S reaches the source electrode 131S, and the opening 40D reaches the drain electrode 131D.

The semiconductor device 1 includes plating base layers 132S and 132D. The plating base layers 132S and 132D extend in parallel to the Y-axis direction. The plating base layer 132S covers the bottom surface and inner wall surface of the opening 40S, and a part of the upper surface of the insulating film 43. The plating base layer 132D covers the bottom surface and inner wall surface of the opening 40D, and a part of the upper surface of the insulating film 43. The plating base layers 132S and 132D include, for example, a titanium (Ti) layer and an Au layer that are laminated upward in this order.

The etching stoppers 133S and 133D extend in parallel to the Y-axis direction. The etching stopper 133S is provided on the plating base layer 132S. The etching stopper 133D is provided on the plating base layer 132D. The etching stoppers 133S and 133D are an electrolytic plating layer, such as an electrolytic Ni plating layer or the like. Resistance of the etching stopper 133S to etching using the reactive gas is higher than resistance of the source electrode 131S to etching using the reactive gas. That is, the etching stopper 133S has higher resistance to etching using the reactive gas than in the source electrode 131S. Resistance of the etching stopper 133S to etching using the reactive gas including chlorine (Cl) may be higher that resistance of the source electrode 131S to etching using the reactive gas including Cl. Also, resistance of the etching stopper 133S to etching using the reactive gas including fluorine (F) may be higher than resistance of the source electrode 131S using the reactive gas including F. The etching stopper 133S is an example of the second metal layer.

The source wire 134S and the drain wire 134D extend in parallel to the Y-axis direction. The source wire 134S is above the source electrode 131S. The source wire 134S is provided on the etching stopper 133S. The source wire 134S is electrically connected to the source electrode 131S via the etching stopper 133S and the plating base layer 132S. The drain wire 134D is above the drain electrode 131D. The drain wire 134D is on the etching stopper 133D. The drain wire 134D is electrically connected to the drain electrode 131D via the etching stopper 133D and the plating base layer 132D. The source wire 134S and the drain wire 134D include, for example, an Au layer. Resistivity of the source wire 134S is lower than resistivity of the source electrode 131S and resistivity of the etching stopper 133S. As illustrated in FIG. 1, a plurality of the drain wires 134D may be connected to a drain pad 32, and a plurality of the source wires 134S may be connected to each other. The source wire 134S is an example of the third metal layer.

The semiconductor device 1 includes an insulating film 44. The insulating film 44 covers the source wire 134S, the drain wire 134D, the etching stopper 133S, the etching stopper 133D, the plating base layer 132S, the plating base layer 132D, and the insulating film 43. For example, the insulating film 44 is a nitride film, such as an SiN film or the like.

Although not illustrated, an opening reaching the gate common connection portion 31 is formed in the insulating film 43, and a gate pad is formed on the insulating film 43, the gate pad contacting the gate common connection portion 31 through this opening. Also, an opening reaching the gate pad and an opening reaching the drain pad 32 are formed in the insulating film 44.

A through-hole 11 penetrating the substrate 10, the semiconductor layer 21, the source electrode 131S, and the plating base layer 132S is formed through the substrate 10, the semiconductor layer 21, the source electrode 131S, and the plating base layer 132S. The through-hole 11 reaches the etching stopper 133S. The etching stopper 133S is exposed to the through-hole 11. At least one through-hole 11 may be formed in each of the source electrodes 131S. A plurality of the through-holes 11 may be formed in each of the source electrodes 131S.

The backside electrode 12 is formed on a lower surface of the etching stopper 133S, an inner wall surface of the through-hole 11, and a lower surface of the substrate 10. The backside electrode 12 is in contact with the etching stopper 133S, and covers the lower surface of the substrate 10 and the inner wall surface of the through-hole 11. The backside electrode 12 is provided on an inner surface of the through-hole 11 and is in direct contact with the etching stopper 133S. For example, the backside electrode 12 is formed of an Au layer. The backside electrode 12 includes, for example, a seed layer and a plating layer. The backside electrode 12 is an example of the fourth metal layer.

### [Production Method for Semiconductor Device]

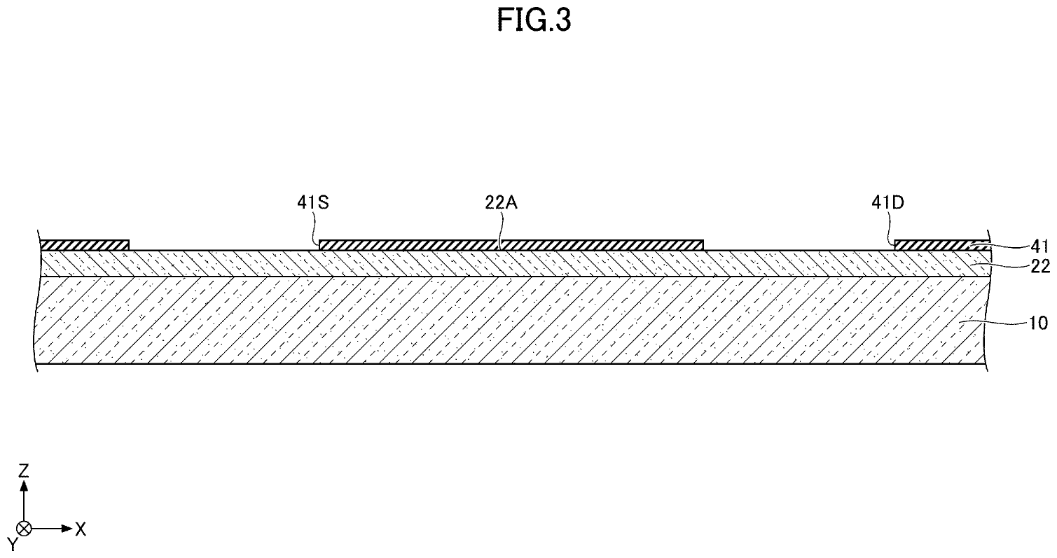

Next, a production method for a semiconductor device 1 according to the first embodiment will be described. FIG. 3 to FIG. 13 are cross-sectional diagrams illustrating the production method for the semiconductor device 1 according to the first embodiment.

First, as illustrated in FIG. 3, the semiconductor layer 22 is formed on the substrate 10, for example, through metal organic chemical vapor deposition (MOCVD). Next, the insulating film 41 is formed on the semiconductor layer 22. The insulating film 41 can be formed, for example, through plasma CVD. Next, the openings 41S and 41D are formed in the insulating film 41. For formation of the openings 41S and 41D, for example, reactive ion etching (RIE) of the insulating film 41 is performed using a resist pattern as a mask. During the RIE of the insulating film 41, for example, the reactive gas including F is used.

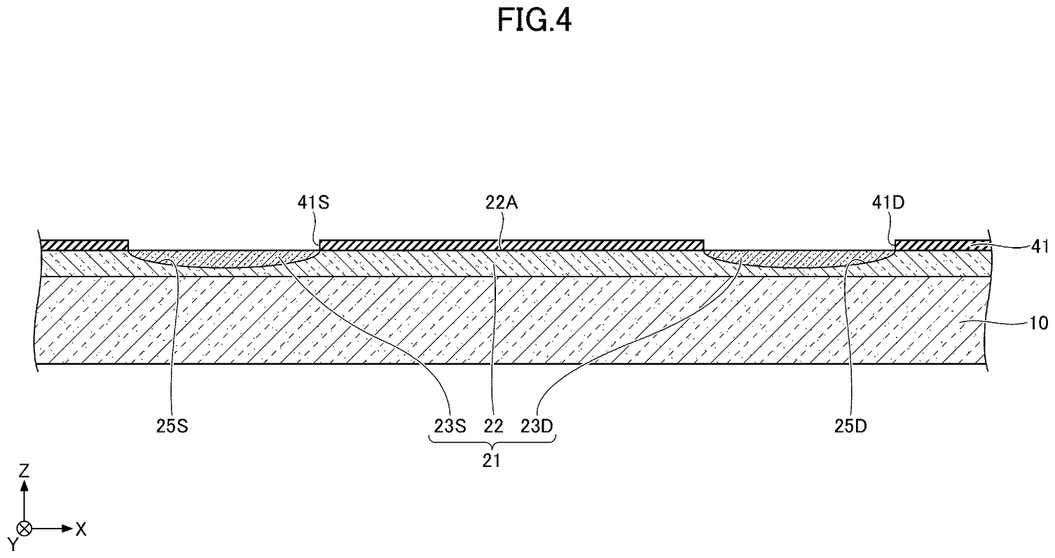

Next, as illustrated in FIG. 4, the recesses 25S and 25D are formed in the upper surface 22A of the b semiconductor layer 22. For formation of the recesses 25S and 25D, RIE of the semiconductor layer 22 is performed using, as a mask, the resist pattern used for formation of the openings 41S and 41D. During the RIE of the semiconductor layer 22, for example, the reactive gas including Cl is used. Next, the semiconductor layer 23S is formed in the recess 25S, and the semiconductor layer 23D is formed in the recess 25D. The semiconductor layers 23S and 23D are formed, for example, by growing crystals of the semiconductor layers through MOCVD, molecular beam epitaxy (MBE), or sputtering, using a mask, and subsequently removing the mask. The semiconductor layers 23S and 23D are what is called re-grown layers.

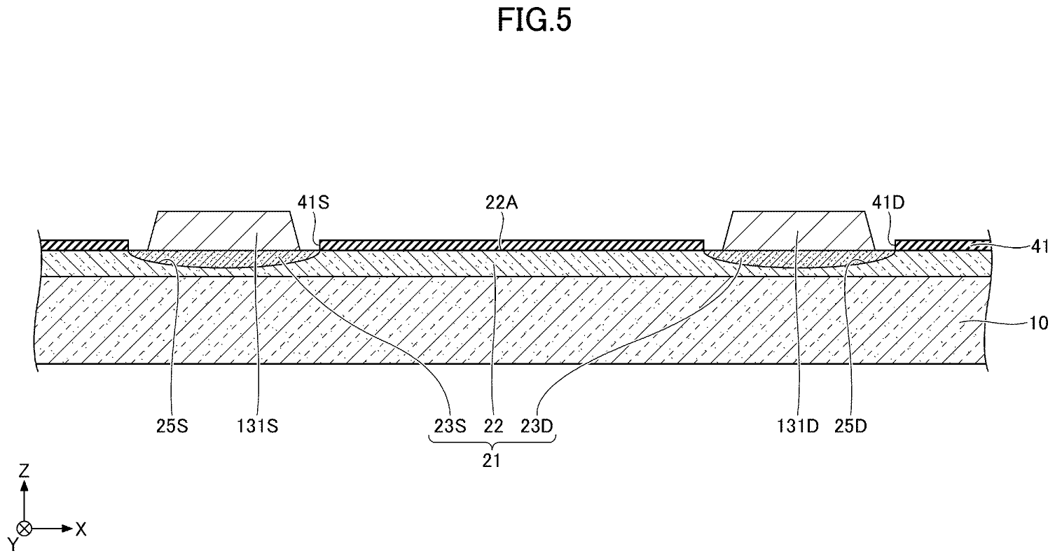

Next, as illustrated in FIG. 5, the source electrode 131S is formed on the semiconductor layer 23S, and the drain electrode 131D is formed on the semiconductor layer 23D. The source electrode 131S and the drain electrode 131D are formed, for example, by growing an Al layer through vapor deposition using a mask, and subsequently removing the mask. That is, the source electrode 131S and the drain electrode 131D can be formed, for example, through vapor deposition and lift-off.

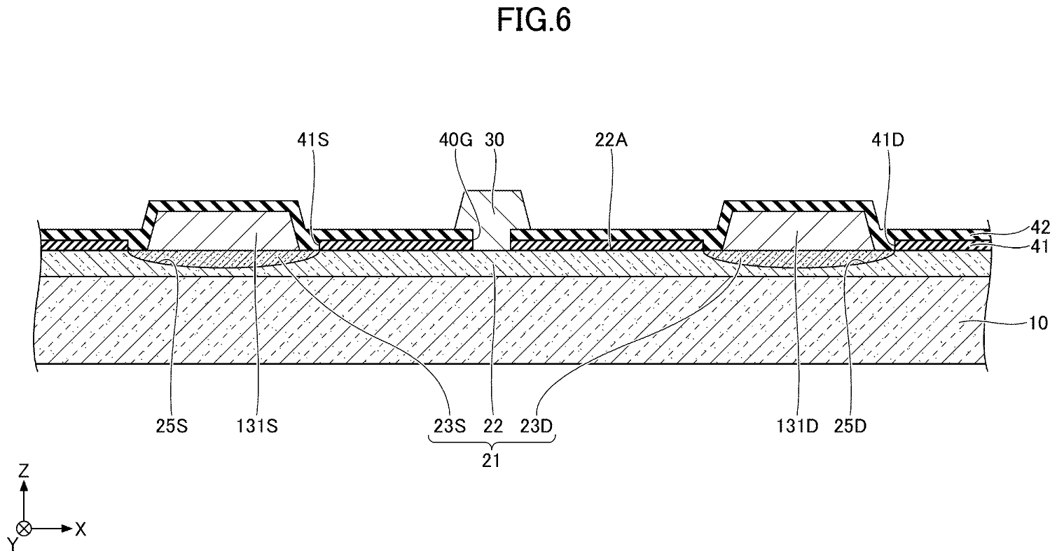

Next, as illustrated in FIG. 6, the insulating film 42 covering the insulating film 41, the semiconductor layer 23S, the semiconductor layer 23D, the source electrode 131S, and the drain electrode 131D is formed. The insulating film 42 can be formed, for example, through plasma CVD. Next, the opening 40G is formed in the laminate of the insulating films 41 and 42. For formation of the opening 40G, for example, RIE is performed by using a resist pattern as a mask. For etching of the insulating films 41 and 42, for example, the reactive gas including F is used. Next, the gate electrode 30 is formed on the insulating film 42. The gate electrode 30 is formed, for example, by growing an Ni layer and an Au layer through vapor deposition using a make, and subsequently removing the mask. That is, the gate electrode 30 can be formed, for example, through vapor deposition and lift-off. The gate electrode 30 makes a Schottky contact with the semiconductor layer 21 through the opening 40G.

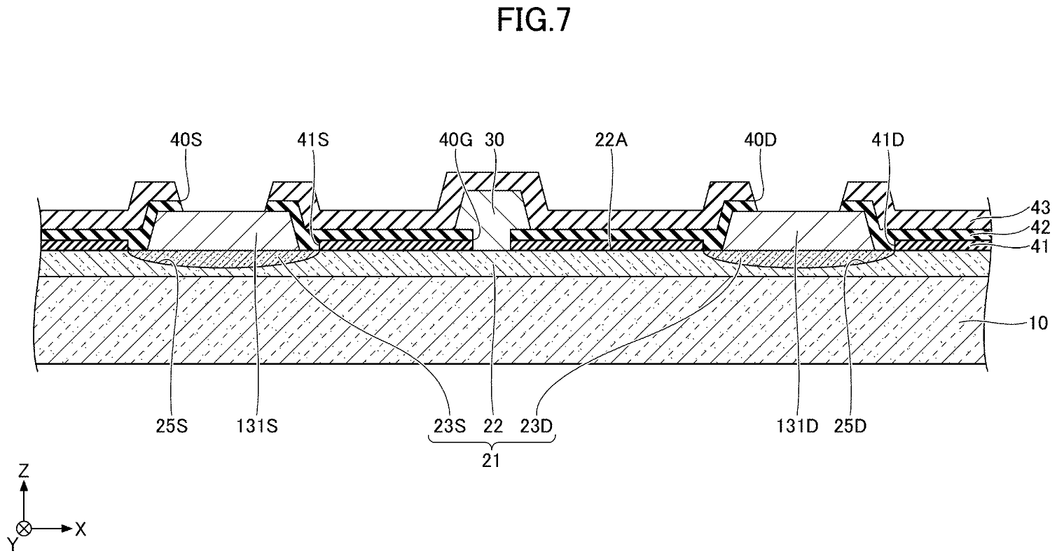

Next, as illustrated in FIG. 7, the insulating film 43 covering the gate electrode 30 and the insulating film 42 is formed. The insulating film 43 can be formed, for example, through plasma CVD. Next, the openings 40S and 40D are formed in the laminate of the insulating films 42 and 43. For formation of the openings 40S and 40D, for example, RIE is performed using a resist pattern as a mask. For etching of the insulating films 42 and 43, for example, the reactive gas including F is used.

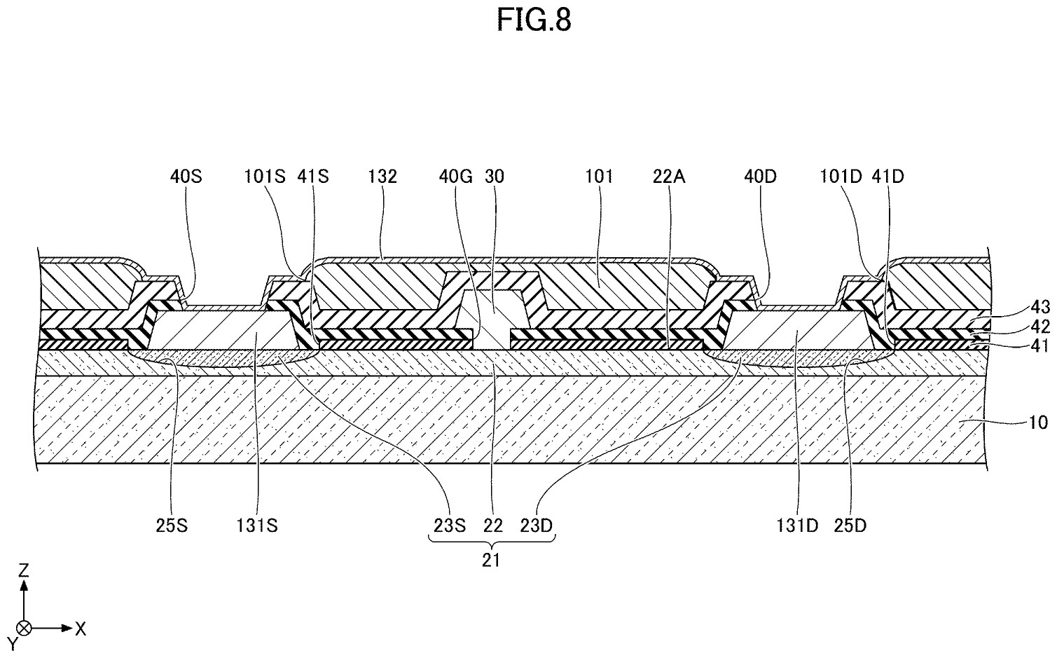

Next, as illustrated in FIG. 8, a resist pattern 101 is formed on the insulating film 43. The resist pattern 101 includes: an opening 101S that is slightly wider, in a plan view, than a region in which the plating base layer 132S is formed; and an opening 101D that is slightly wider, in a plan view, than a region in which the plating base layer 132D is formed. Next, a metal layer 132 to form the plating base layers 132S and 132D is formed on the entirety of the upper surface. The metal layer 132 can be formed, for example, through sputtering.

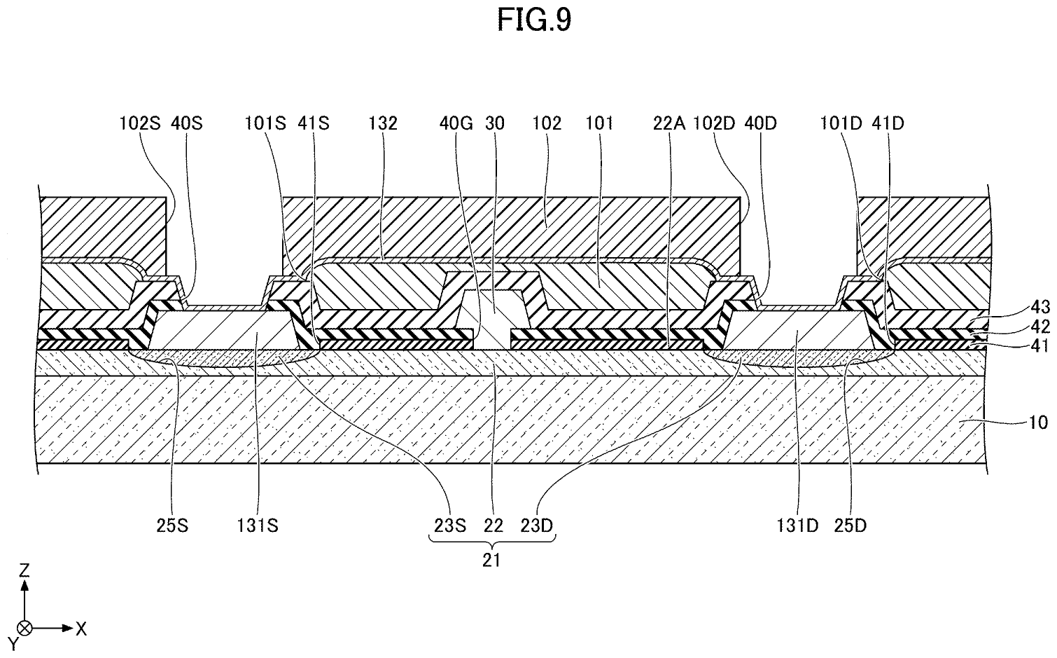

Next, as illustrated in FIG. 9, a resist pattern 102 is formed on the metal layer 132. The resist pattern 102 includes an opening 102S in which the etching stopper 133S and the source wire 134S are formed, and an opening 102D in which the etching stopper 133D and the drain wire 134D are formed.

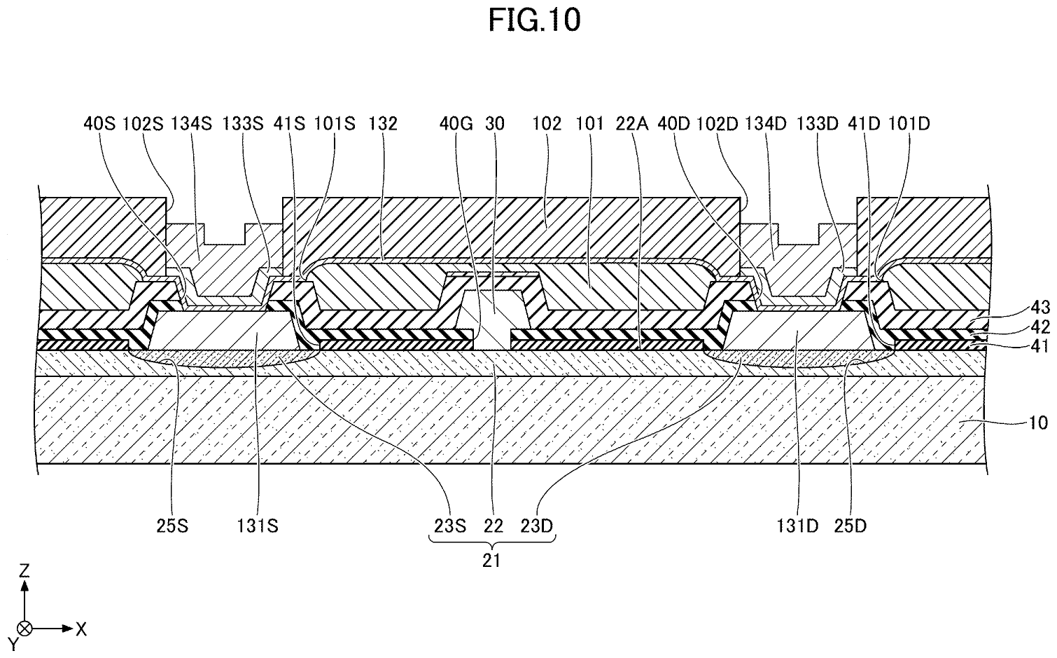

Next, as illustrated in FIG. 10, the etching stopper 133S and the source wire 134S are formed on the metal layer 132 in the opening 102S, and the etching stopper 133D and the drain wire 134D are formed on the metal layer 132 in the opening 102D. For example, the etching stoppers 133S and 133D include an Ni layer, and the source wire 134S and the drain wire 134D include an Au layer. For formation of the etching stopper 133S, the etching stopper 133D, the source wire 134S, and the drain wire 134D, for example, electrolytic plating is performed using the metal layer 132 as an electric power supply path.

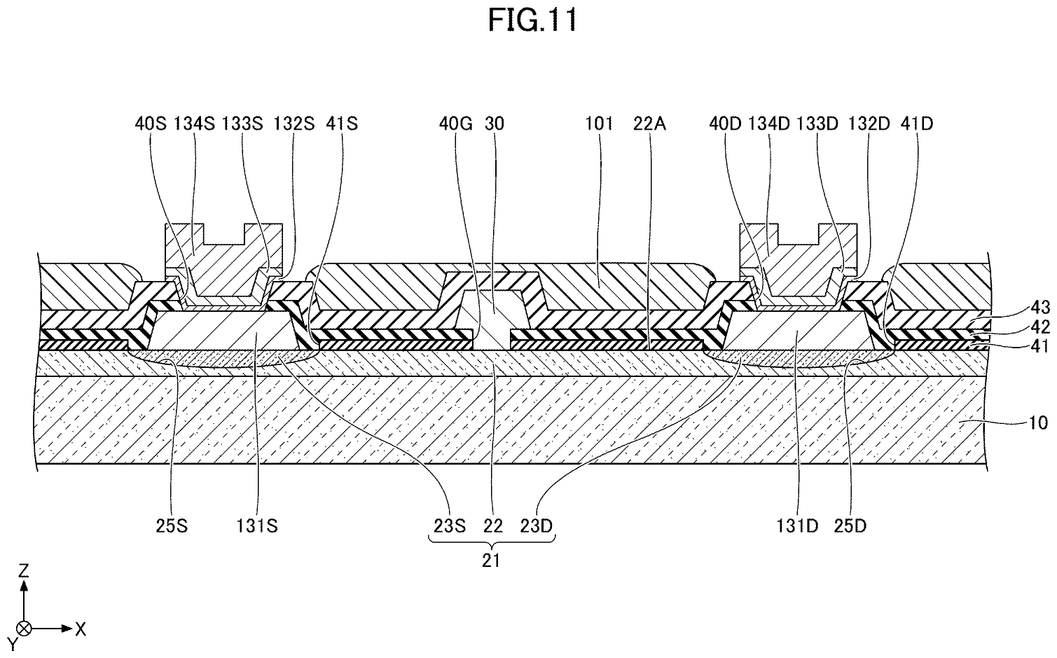

Next, as illustrated in FIG. 11, the resist pattern 102 is removed. Next, a portion of the metal layer 132 not covered by the source wire 134S and the drain wire 134D is removed through etching. As a result, the plating base layers 132S and 132D are formed from the metal layer 132.

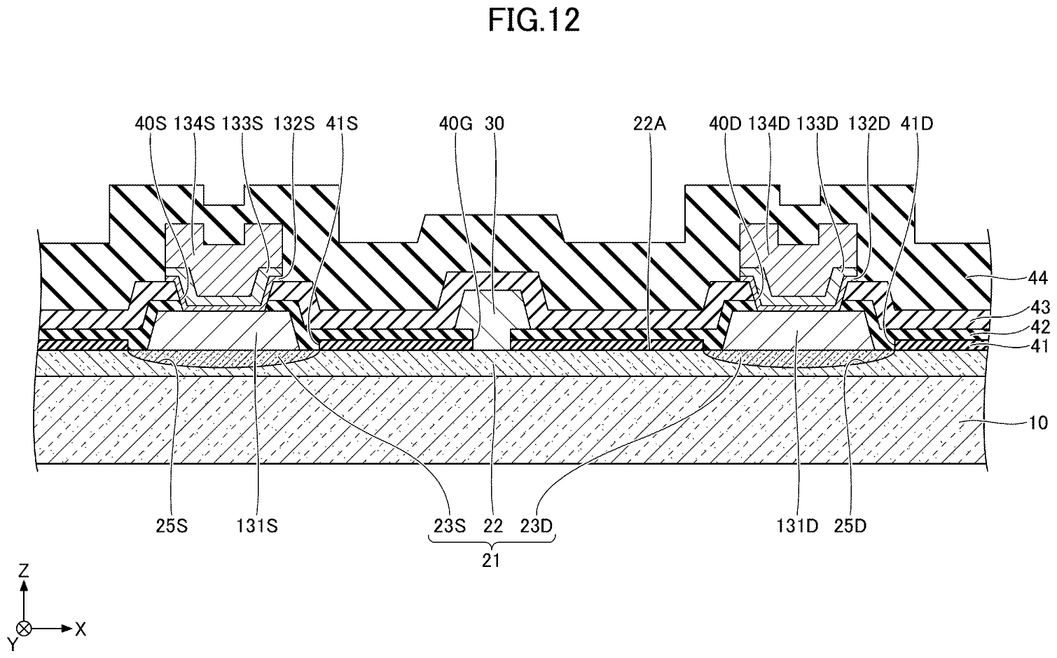

Next, as illustrated in FIG. 12, the resist pattern 101 is removed. Next, the insulating film 44 covering the source wire 134S, the drain wire 134D, the etching stopper 133S, the etching stopper 133D, the plating base layer 132S, the plating base layer 132D, and the insulating film 43 is formed. The insulating film 44 can be formed, for example, through plasma CVD.

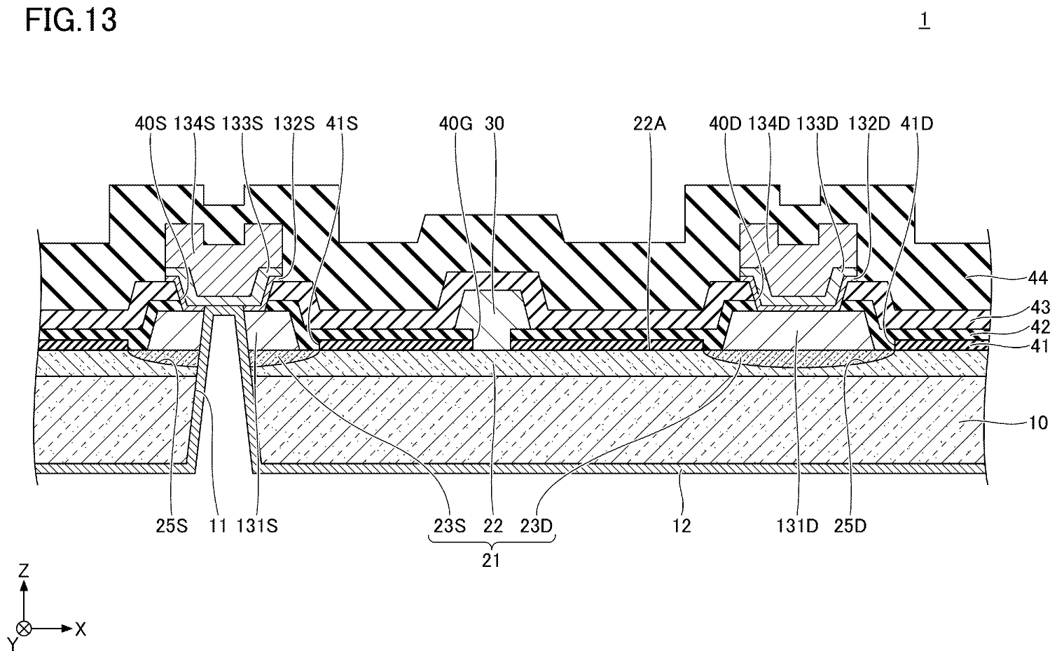

Next, as illustrated in FIG. 13, the through-hole 11 penetrating the substrate 10, the semiconductor layer 21, the source electrode 131S, and the plating base layer 132S is formed through the substrate 10, the semiconductor layer 21, the source electrode 131S, and the plating base layer 132S. The through-hole 11 is formed to reach the etching stopper 133S. The etching stopper 133S is exposed to the through-hole 11. For formation of the through-hole 11, the substrate 10 is etched, and subsequently the semiconductor layer 21, the source electrode 131S, and the plating base layer 132S are etched. During etching of the substrate 10, for example, the reactive gas including F is used. During etching of the semiconductor layer 21, the source electrode 131S, and the plating base layer 132S, for example, the reactive gas including Cl or F is used. The etching stopper 133S, e.g., an Ni layer, has high resistance to etching using the reactive gas including Cl and the reactive gas including F. The reactive gas including F may be used to successively etch the substrate 10, the semiconductor layer 21, the source electrode 131S, and the plating base layer 132S. After formation of the through-hole 11, the backside electrode 12 is formed. The backside electrode 12 contacts the etching stopper 133S and covers the lower surface of the substrate 10 and the inner wall surface of the through-hole 11.

In this manner, the semiconductor device 1 according to the first embodiment can be produced.

The semiconductor device 1 according to the first embodiment includes the etching stopper 133S between the source electrode 131S and the source wire 134S. Thus, in a plan view, the region for the etching stopper 133S does not need to be provided apart from the region for the source electrode 131S. Therefore, this configuration can be downsized compared to a configuration in which the region for the etching stopper 133S is provided apart from the region for the source electrode 131S in a plan view.

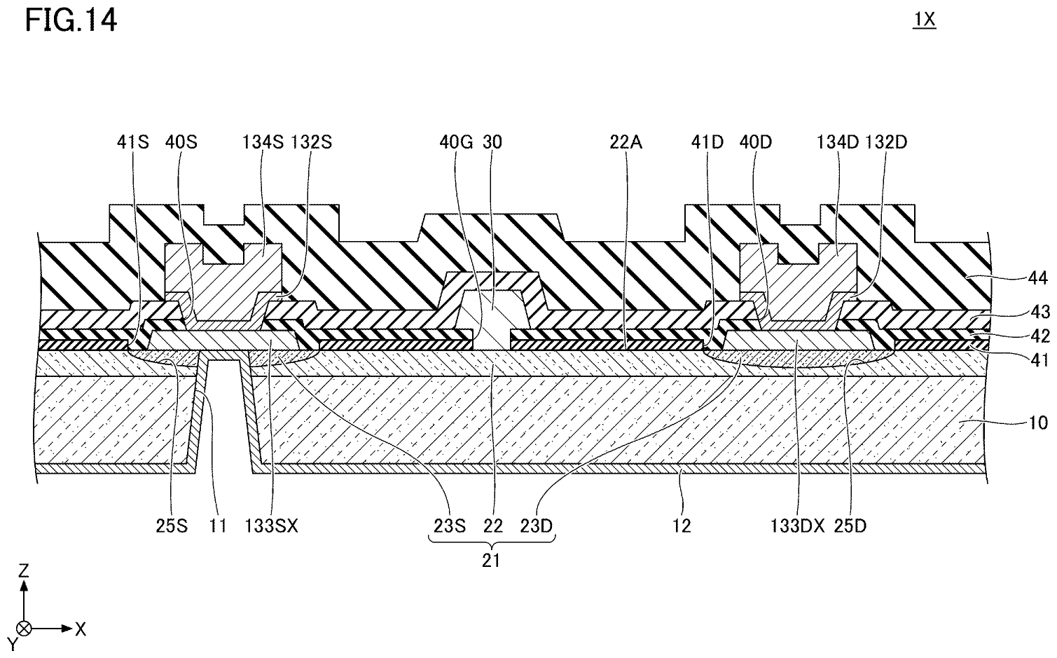

Considering downsizing alone, it is also considered that the etching stopper 133S is configured to make an Ohmic contact with the semiconductor layer 21. In this case, however, it becomes challenging to ensure that the etching stopper 133S has a sufficient thickness. Here, a referential example will be described. FIG. 14 is a cross-sectional diagram illustrating a semiconductor device according to the referential example.

As illustrated in FIG. 14, a semiconductor device 1X according to the referential example includes an etching stopper 133SX instead of the source electrode 131S and an etching stopper 133DX instead of the drain electrode 131D. The etching stopper 133SX is provided on the semiconductor layer 23S and makes an Ohmic contact with the semiconductor layer 23S. The etching stopper 133DX is provided on the semiconductor layer 23D and makes an Ohmic contact with the semiconductor layer 23D. The etching stoppers 133SX and 133DX are an Ni layer formed through vapor deposition and lift-off. The plating base layer 132S is in contact with the upper surface of the etching stopper 133SX, and the source wire 134S is in direct contact with the plating base layer 132S. The plating base layer 132D is in contact with the upper surface of the etching stopper 133DX, and the drain wire 134D is in direct contact with the plating base layer 132D.

The other aspects of the configuration of the referential example are the same as in the first embodiment.

For formation of the etching stoppers 133SX and 133DX, vapor deposition of an Ni layer is performed. However, it is challenging to form a thick Ni layer through vapor deposition. For example, an Ni layer having a thickness of about 500 nm can be readily formed through plating. Meanwhile, the thickness of an Ni layer that can be readily formed through vapor deposition is about 100 nm. Although Ni has favorable resistance to etching using the reactive gas including Cl or F, the through-hole 11 may also penetrate the etching stopper 133SX during formation of the through-hole 11. Lowering an etching rate during formation of the through-hole 11 can avoid penetration of the through-hole 11 through the etching stopper 133SX. However, this case involves a longer lead time and reduced productivity. In FIG. 14, for the sake of convenience, the etching stoppers 133SX and 133DX are illustrated to be thicker than actual ones.

It is also considered that the etching stoppers 133SX and 133DX are formed through plating. However, when the etching stoppers 133SX and 133DX are formed through plating, resulting dimensional accuracy is lower than when the etching stoppers 133SX and 133DX are formed through vapor deposition. The distance between the gate electrode 30 and the metal layer in an Ohmic contact with the semiconductor layer 23S largely impacts characteristics of a HEMT. Therefore, reduction in dimensional accuracy of the etching stopper 133SX can lead to reduction in reliability and increase in variation of characteristics.

Meanwhile, in the present embodiment, the source electrode 131S and the drain electrode 131D can be formed through vapor deposition and lift-off, and the etching stopper 133S can be formed through electrolytic plating. Therefore, the etching stopper 133S having a large thickness is formed while ensuring high dimensional accuracy of the source electrode 131S and the drain electrode 131D, and penetration of the through-hole 11 through the etching stopper 133S can be prevented. This readily realizes downsizing.

When the semiconductor layer 21 includes the semiconductor layer 23S and the source electrode 131S makes an Ohmic contact with the semiconductor layer 23S, it is possible to reduce the contact resistance between the source electrode 131S and the semiconductor layer 21. Also, when the semiconductor layer 21 includes the semiconductor layer 23D and the drain electrode 131D makes an Ohmic contact with the semiconductor layer 23D, it is possible to reduce the contact resistance between the drain electrode 131D and the semiconductor layer 21.

When the etching stopper 133S includes an Ni layer exposed to the through-hole 11, excellent resistance to etching during formation of the through-hole 11 is readily achieved. Also, by performing electrolytic plating using the plating base layer 132S as an electric power supply path, an electrolytic Ni plating layer serving as the etching stopper 133S having a large thickness is readily formed.

When the reactive gas includes chlorine, the semiconductor layer 21 is readily etched. When the reactive gas includes fluorine, the substrate 10 and the semiconductor layer 21 are readily etched. When the substrate 10 is a silicon carbide substrate, the semiconductor layer 21 readily has favorable crystallinity.

When the source electrode 131S includes a titanium layer, a tantalum layer, a gold layer, or an aluminum layer, the titanium layer, the tantalum layer, the gold layer, or the aluminum layer being in direct contact with the semiconductor layer 21, the source electrode 131S readily makes an Ohmic contact with the semiconductor layer 21. Also, when the drain electrode 131D includes an aluminum layer in direct contact with the semiconductor layer 21, the drain electrode 131D readily makes an Ohmic contact with the semiconductor layer 21.

### Second Embodiment

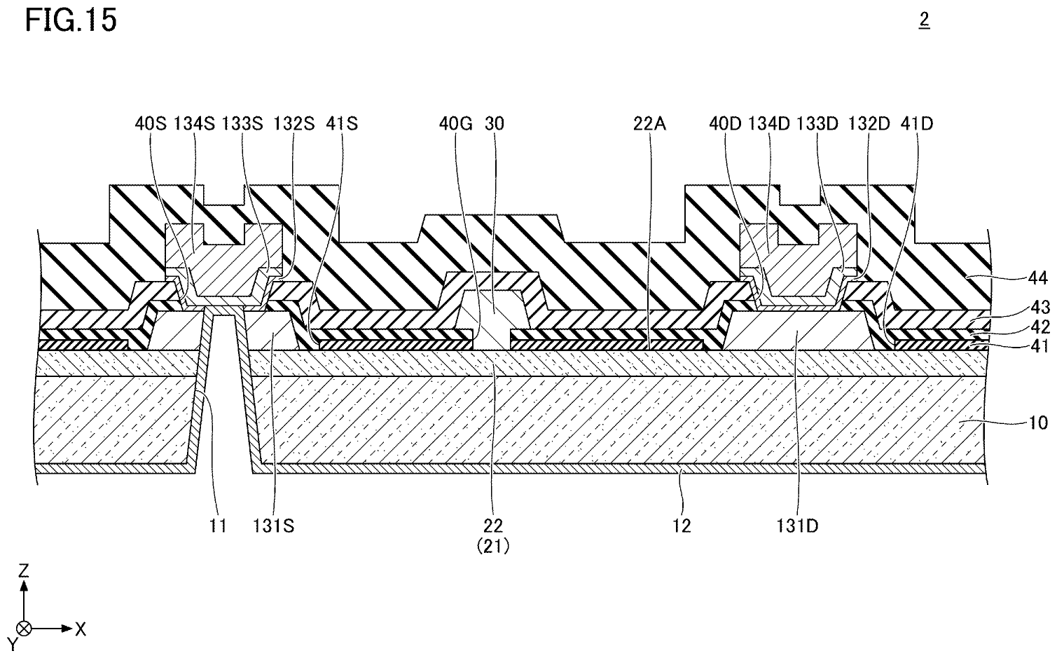

Next, a second embodiment will be described. The second embodiment is different from the first embodiment mainly in terms of the configuration of the semiconductor layer 21. FIG. 15 is a cross-sectional diagram illustrating a semiconductor device according to the second embodiment.

As illustrated in FIG. 15, a semiconductor device 2 according to the second embodiment does not include the recesses 25S and 25D in the semiconductor layer 22. The semiconductor layer 21 includes the semiconductor layer 22, but does not include the semiconductor layers 23S and 23D.

The other configuration of the second embodiment is the same as in the first embodiment.

In the second embodiment, the etching stopper 133S having a large thickness is formed while ensuring high dimensional accuracy of the source electrode 131S, and penetration of the through-hole 11 through the etching stopper 133S can be prevented. This readily realizes downsizing.

### Third Embodiment

Next, a third embodiment will be described. The third embodiment is different from the first embodiment mainly in terms of the configuration of the etching stopper.

### [Configuration of Semiconductor Device]

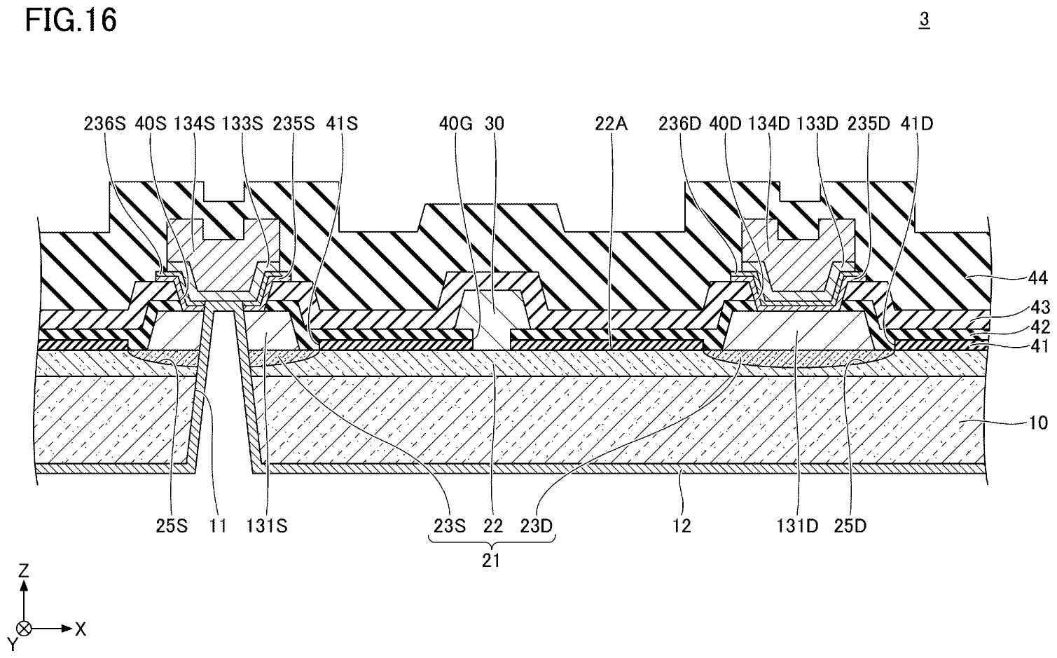

A configuration of the semiconductor device according to the third embodiment will be described. FIG. 16 is a b cross-sectional diagram illustrating a semiconductor device according to the third embodiment.

As illustrated in FIG. 16, a semiconductor device 3 according to the third embodiment includes: an adhesion layer 235S and a catalytic layer 236S instead of the plating base layer 132S; and an adhesion layer 235D and a catalytic layer 236D instead of the plating base layer 132D. The adhesion layer 235S covers the bottom surface and inner wall surface of the opening 40S, and a part of the upper surface of the insulating film 43. The catalytic layer 236S is provided on the adhesion layer 235S. The adhesion layer 235D covers the bottom surface and inner wall surface of the opening 40D, and a part of the upper surface of the insulating film 43. The catalytic layer 236D is provided on the adhesion layer 235D. The adhesion layer 235S is in direct contact with the source electrode 131S, and the adhesion layer 235D is in direct contact with the drain electrode 131D. The adhesion layer 235S and the catalytic layer 236S are in direct contact with each other, and the adhesion layer 235D and the catalytic layer 236D are in direct contact with each other. For example, the adhesion layers 235S and 235D are a Ti layer, and the catalytic layers 236S and 236D are palladium (Pd) layer. The adhesion layer 235S adheres the catalytic layer 236S to the source electrode 131S, and the adhesion layer 235D adheres the catalytic layer 236D to the drain electrode 131D.

Also, in the semiconductor device 3, the etching stoppers 133S and 133D are an electroless plating layer, such as an electroless Ni plating layer or the like. In a plan view, the adhesion layer 235S and the catalytic layer 236S may extend beyond the source wire 134S and the etching stopper 133S, and the adhesion layer 235D and the catalytic layer 236D may extend beyond the drain wire 134D and the etching stopper 133D.

The insulating film 44 covers the source wire 134S, the drain wire 134D, the etching stopper 133S, the etching stopper 133D, the catalytic layer 236S, the catalytic layer 236D, the adhesion layer 235S, the adhesion layer 235D, and the insulating film 43.

The through-hole 11 is formed in the substrate 10, the semiconductor layer 21, the source electrode 131S, the adhesion layer 235S, and the catalytic layer 236S. The through-hole 11 penetrates the substrate 10, the semiconductor layer 21, the source electrode 131S, the adhesion layer 235S, and the catalytic layer 236S.

The other configuration of the third embodiment is the same as in the first embodiment.

### [Production Method for Semiconductor Device]

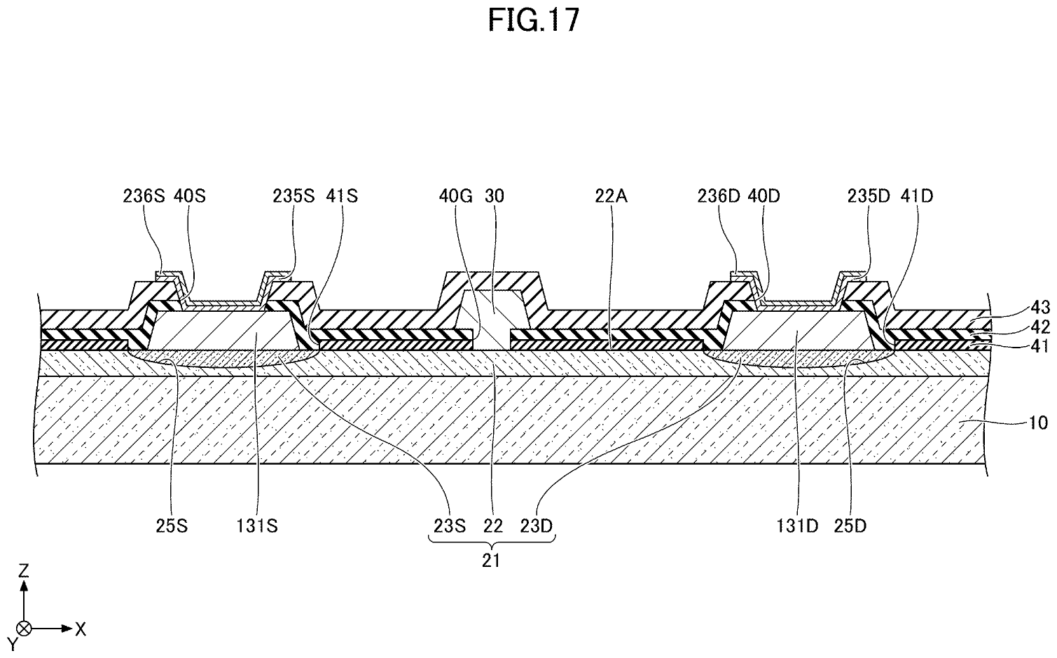

Next, a production method for a semiconductor device 3 according to the third embodiment will be described. FIG. 17 to FIG. 22 are cross-sectional diagrams illustrating the production method for the semiconductor device 3 according to the third embodiment.

First, like in the first embodiment, a process to the formation of the openings 40S and 40D is performed (see FIG. 7). Next, as illustrated in FIG. 17, a laminate of the adhesion layer 235S and the catalytic layer 236S and a laminate of the adhesion layer 235D and the catalytic layer 236D are formed. The laminate of the adhesion layer 235S and the catalytic layer 236S and the laminate of the adhesion layer 235D and the catalytic layer 236D are formed, for example, by growing a Ti layer and a Pd layer through vapor deposition using a make, and subsequently removing the mask. That is, the laminate of the adhesion layer 235S and the catalytic layer 236S and the laminate of the adhesion layer 235D and the catalytic layer 236D can be formed, for example, through vapor deposition and lift-off.

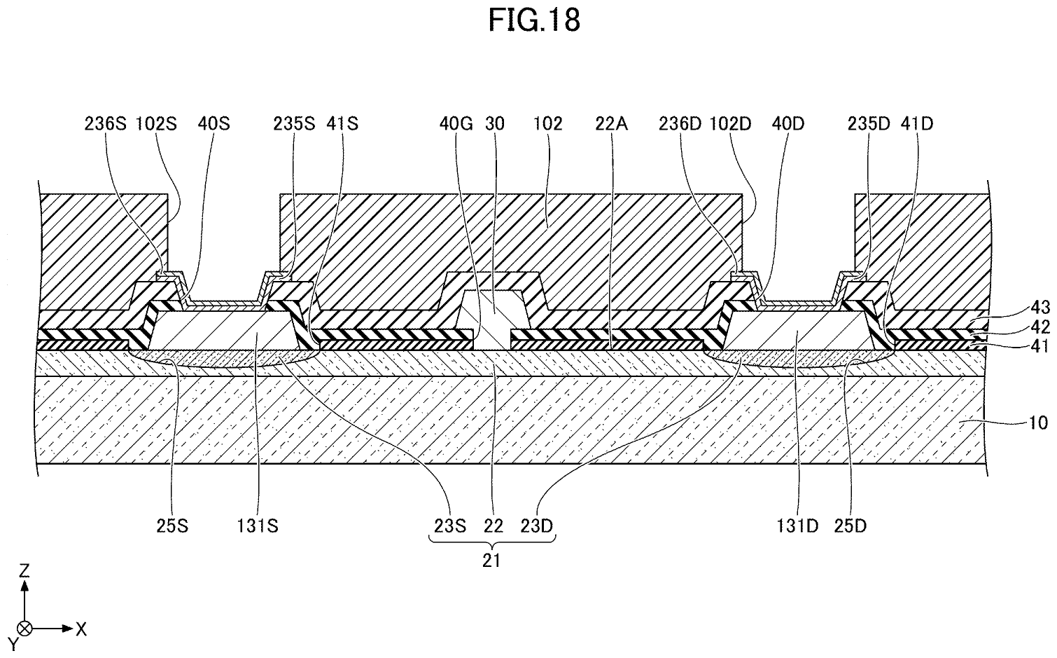

Next, as illustrated in FIG. 18, the resist pattern 102 is formed on the insulating film 43, the catalytic layer 236S, and the catalytic layer 236D. The resist pattern 102 includes the openings 102S and 102D.

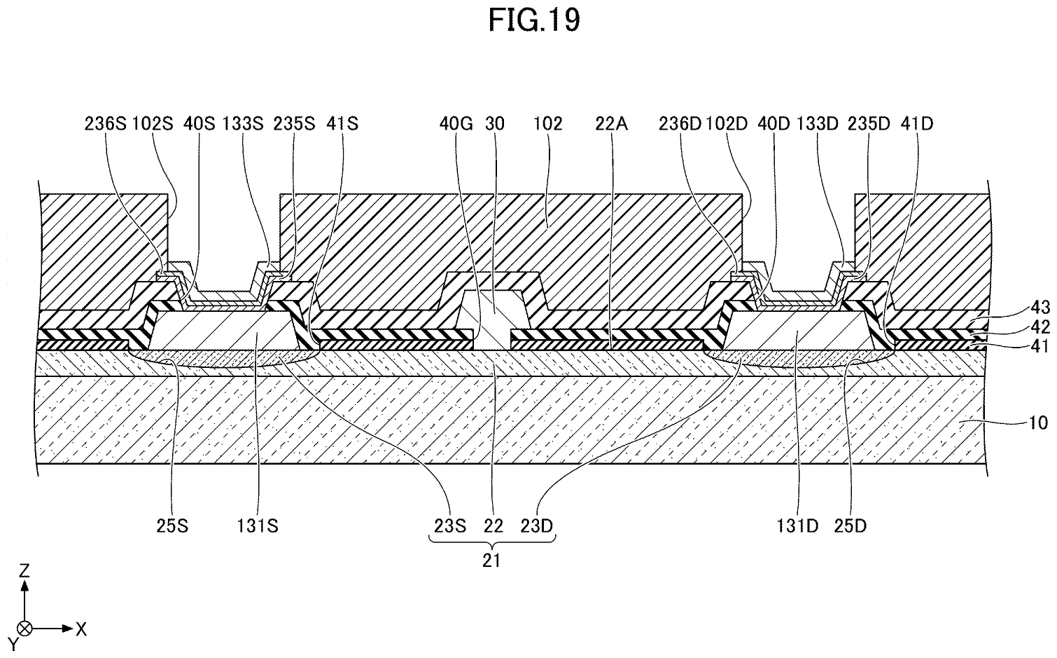

Next, as illustrated in FIG. 19, the etching stopper 133S is formed on the catalytic layer 236S, and the etching stopper 133D is formed on the catalytic layer 236D. The etching stoppers 133S and 133D can be formed, for example, through self-catalytic electroless plating. For example, the etching stoppers 133S and 133D include an Ni layer including phosphorus (P).

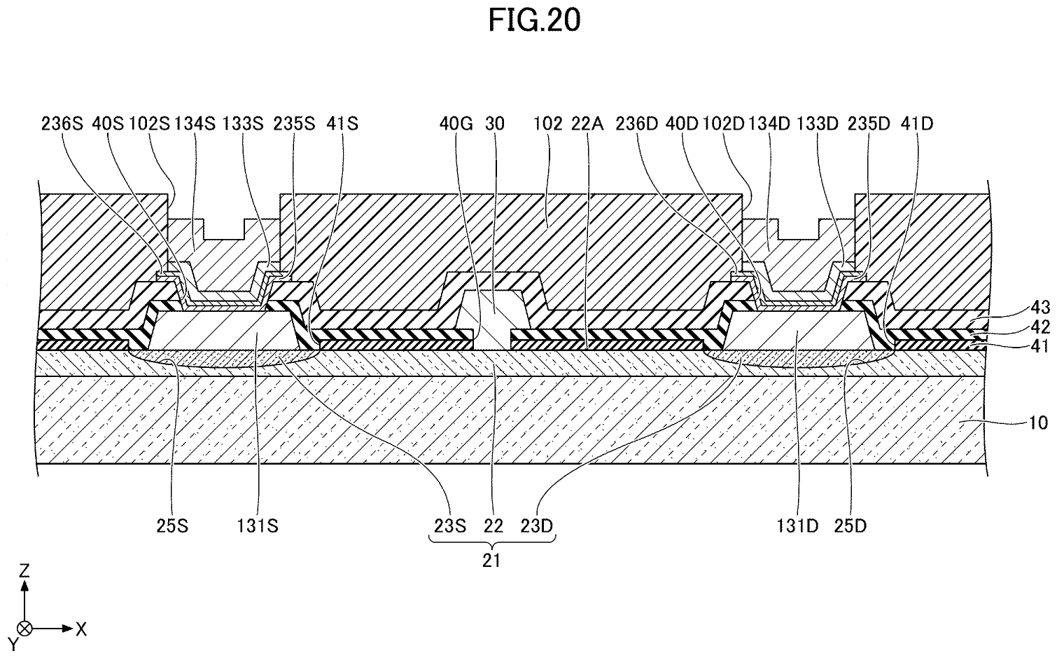

Next, as illustrated in FIG. 20, the source wire 134S is formed on the etching stopper 133S, and the drain wire 134D is formed on the etching stopper 133D. The source wire 134S and the drain wire 134D are formed, for example, by modifying the surfaces of the etching stoppers 133S and 133D with Au through substitution-type electroless plating of Au, and subsequently forming an Au layer through self-catalytic electroless plating.

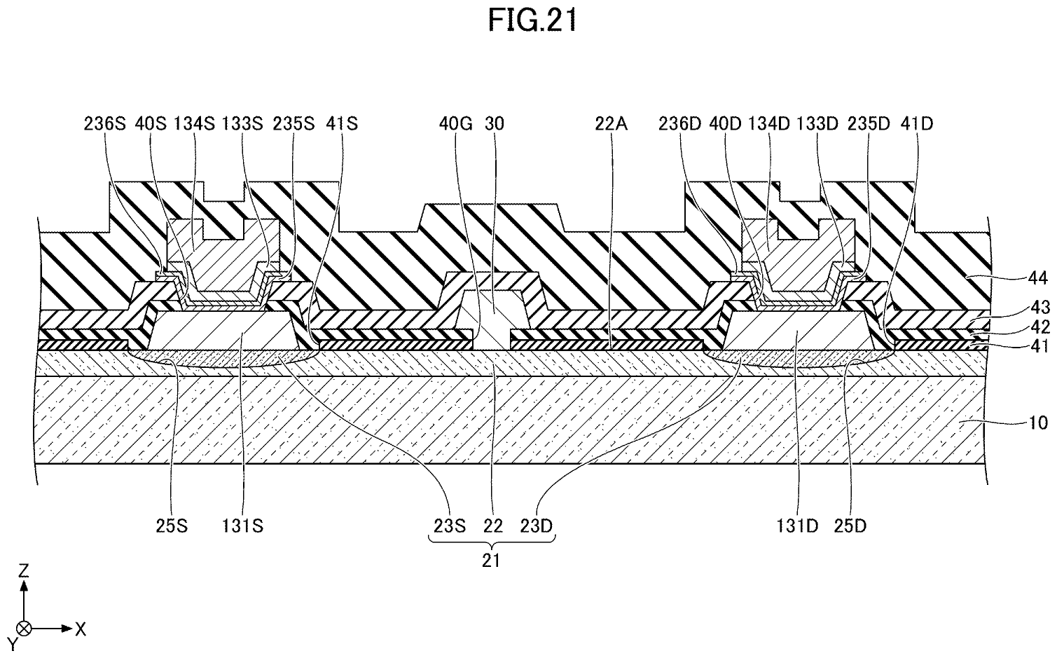

Next, as illustrated in FIG. 21, the resist pattern 102 is removed. Next, the insulating film 44 covering the source wire 134S, the drain wire 134D, the etching stopper 133S, the etching stopper 133D, the catalytic layer 236S, the catalytic layer 236D, the adhesion layer 235S, the adhesion layer 235D, and the insulating film 43 is formed.

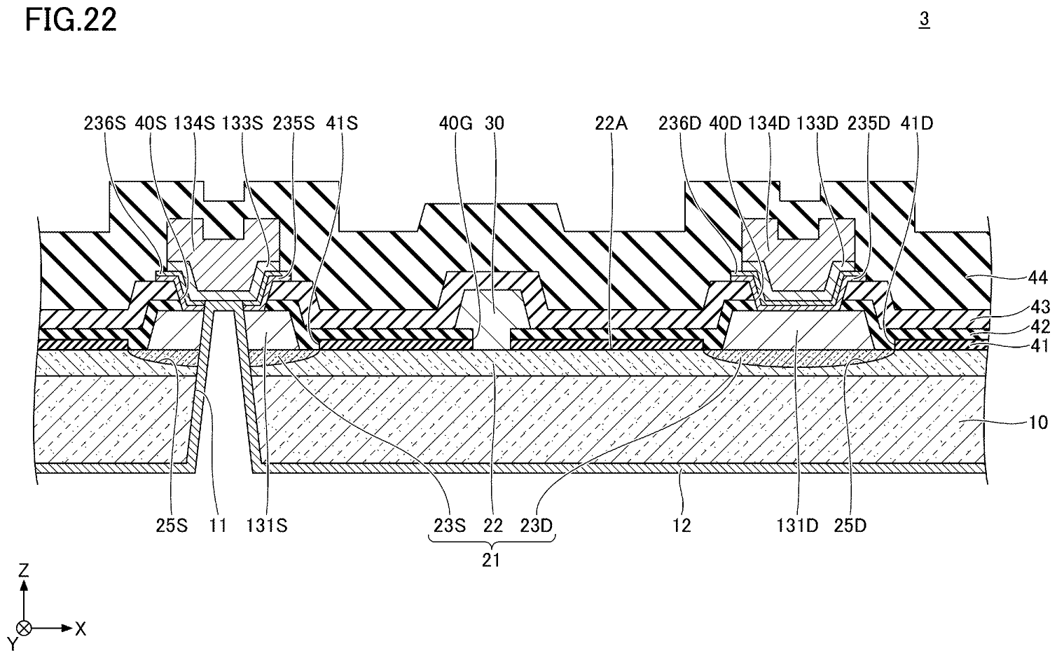

Next, as illustrated in FIG. 22, the through-hole 11 penetrating the substrate 10, the semiconductor layer 21, the source electrode 131S, the adhesion layer 235S, and the catalytic layer 236S is formed through the b substrate 10, the semiconductor layer 21, the source electrode 131S, the adhesion layer 235S, and the catalytic layer 236S. The through-hole 11 is formed to reach the etching stopper 133S. The etching stopper 133S is exposed to the through-hole 11. For formation of the through-hole 11, the substrate 10 is etched, and subsequently the semiconductor layer 21, the source electrode 131S, the adhesion layer 235S, and the catalytic layer 236S are etched. For etching of the substrate 10, for example, the reactive gas including F is used. For etching of the semiconductor layer 21, the source electrode 131S, the adhesion layer 235S, and the catalytic layer 236S, for example, the reactive gas including Cl or F is used. The reactive gas including F may be used to successively etch the substrate 10, the semiconductor layer 21, the source electrode 131S, the adhesion layer 235S, and the catalytic layer 236S. After formation of the through-hole 11, the backside electrode 12 is formed. The backside electrode 12 contacts the etching stopper 133S and covers the lower surface of the substrate 10 and the inner wall surface of the through-hole 11.

In this manner, the semiconductor device 3 according to the third embodiment can be produced.

The third embodiment can produce the same effects as in the first embodiment. Also, by performing electroless plating using the catalytic layer 236S, an electroless Ni plating layer serving as the etching stopper 133S having a large thickness is readily formed.

### Fourth Embodiment

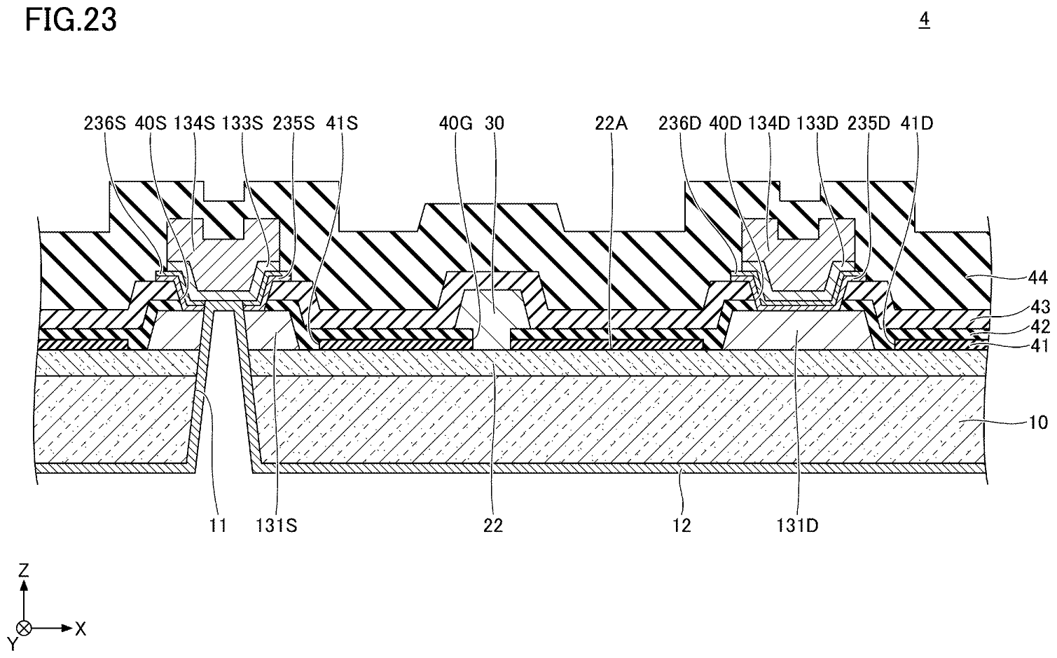

Next, a fourth embodiment will be described. The fourth embodiment is different from the third embodiment mainly in terms of the configuration of the semiconductor layer 21. FIG. 23 is a cross-sectional diagram illustrating a semiconductor device according to the fourth embodiment.

As illustrated in FIG. 23, a semiconductor device 4 according to the fourth embodiment does not include the recesses 25S and 25D in the semiconductor layer 22. The semiconductor layer 21 includes the semiconductor layer 22, but does not include the semiconductor layers 23S and 23D.

The other configuration of the fourth embodiment is the same as in the third embodiment.

In the fourth embodiment, the etching stopper 133S having a large thickness is formed while ensuring high dimensional accuracy of the source electrode 131S, and penetration of the through-hole 11 through the etching stopper 133S can be prevented. This readily realizes downsizing.

### Fifth Embodiment

Next, a fifth embodiment will be described. The fifth embodiment is different from the third embodiment mainly in terms of the configurations of the source electrode and the drain electrode.

### [Configuration of Semiconductor Device]

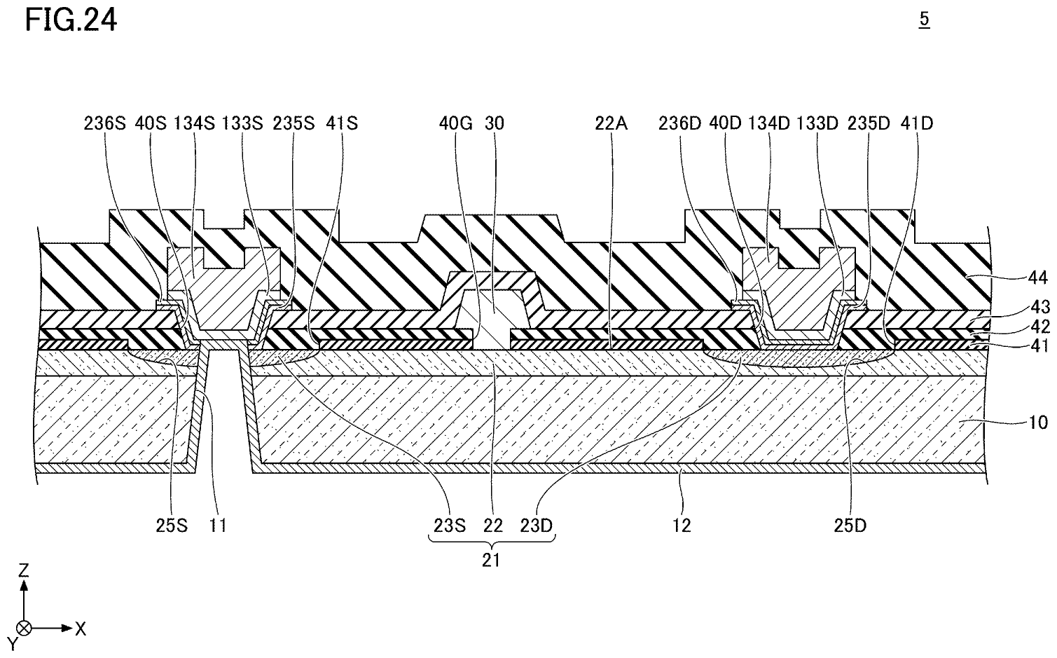

A configuration of the semiconductor device according to the fifth embodiment will be described. FIG. 24 is a cross-sectional diagram illustrating the semiconductor device according to the fifth embodiment.

As illustrated in FIG. 24, a semiconductor device 5 according to the fifth embodiment does not include the source electrode 131S and the drain electrode 131D. The insulating film 42 covers the insulating film 41, the semiconductor layer 23S, and the semiconductor layer 23D. The opening 40S reaches the semiconductor layer 23S, and the opening 40D reaches the semiconductor layer 23D. The adhesion layer 235S is in direct contact with the semiconductor layer 23S, and the adhesion layer 235D is in direct contact with the semiconductor layer 23D. The adhesion layer 235S adheres the catalytic layer 236S to the semiconductor layer 23S, and the adhesion layer 235D adheres the catalytic layer 236D to the semiconductor layer 23D. The adhesion layer 235S and the catalytic layer 236S make an Ohmic contact with the semiconductor layer 23S, and the adhesion layer 235D and the catalytic layer 236D make an Ohmic contact with the semiconductor layer 23D. In the fifth embodiment, a laminate of the adhesion layer 235S and the catalytic layer 236S is an example of the first metal layer.

The other configuration of the fifth embodiment is the same as in the third embodiment.

### [Production Method for Semiconductor Device]

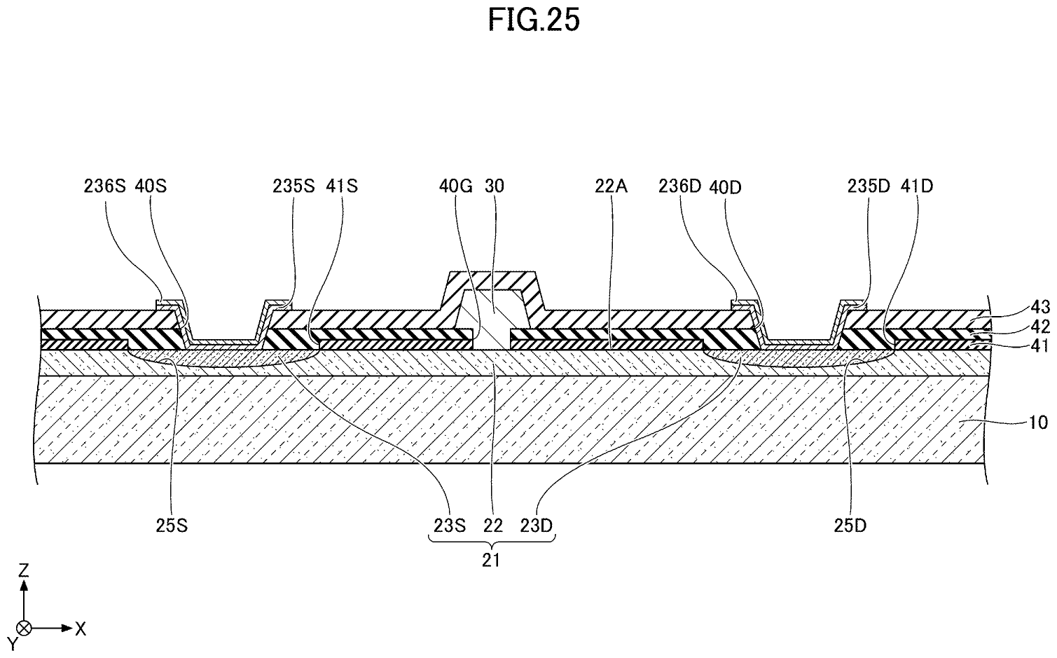

Next, a production method for a semiconductor device 5 according to the fifth embodiment will be described. FIG. 25 to FIG. 27 are cross-sectional diagrams illustrating the production method for the semiconductor device 5 according to the fifth embodiment.

First, like in the first embodiment, a process to the formation of the semiconductor layers 23S and 23D is performed (see FIG. 4). Next, as illustrated in FIG. 25, the insulating film 42 covering the insulating film 41, the semiconductor layer 23S, and the semiconductor layer 23D is formed. Next, the opening 40G is formed in the laminate of the insulating films 41 and 42. Next, the gate electrode 30 is formed on the insulating film 42. The gate electrode 30 makes a Schottky contact with the semiconductor layer 21 through the opening 40G. Next, the insulating film 43 covering the gate electrode 30 and the insulating film 42 is formed. Next, the openings 40S and 40D are formed in the laminate of the insulating films 42 and 43. Next, like in the third embodiment, the laminate of the adhesion layer 235S and the catalytic layer 236S and the laminate of the adhesion layer 235D and the catalytic layer 236D are formed.

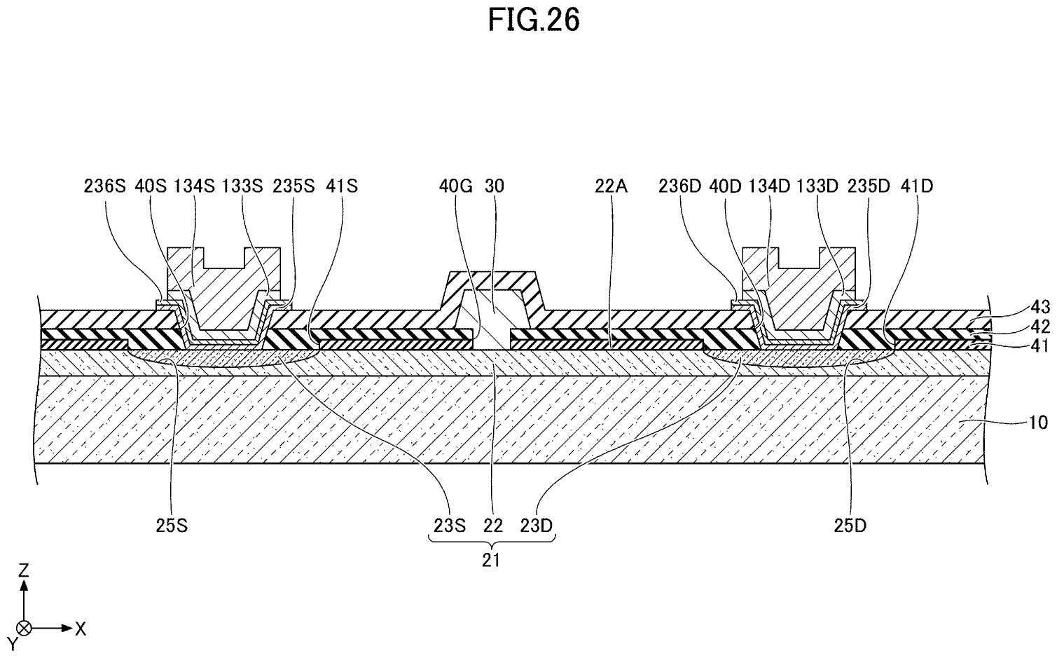

Next, as illustrated in FIG. 26, the resist pattern 102 (not illustrated) is used to form a laminate of the etching stopper 133S and the source wire 134S on the catalytic layer 236S and a laminate of the etching stopper 133D and the drain wire 134D on the catalytic layer 236D.

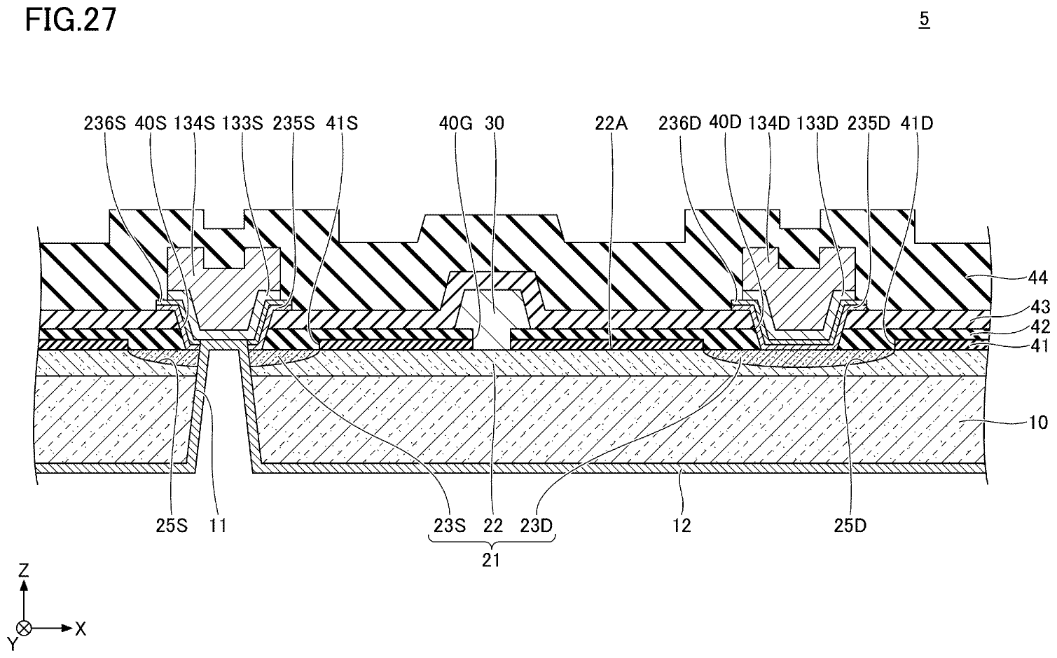

Next, as illustrated in FIG. 27, like in the third embodiment, the insulating film 44, the through-hole 11, and the backside electrode 12 are formed.

In this manner, the semiconductor device 5 according to the fifth embodiment can be produced.

In the fifth embodiment, the etching stopper 133S having a large thickness is formed while ensuring high dimensional accuracy of the laminate of the adhesion layer 235S and the catalytic layer 236S, and penetration of the through-hole 11 through the etching stopper 133S can be prevented. This readily realizes downsizing. Furthermore, there is no need to form the source electrode 131S and the drain electrode 131D, and thus it is possible to reduce a lead time and increase productivity. It is also possible to make the semiconductor device thinner.

### Sixth Embodiment

Next, a sixth embodiment will be described. The sixth embodiment is different from the third embodiment mainly in terms of the configurations of the source electrode and the drain electrode.

### [Configuration of Semiconductor Device]

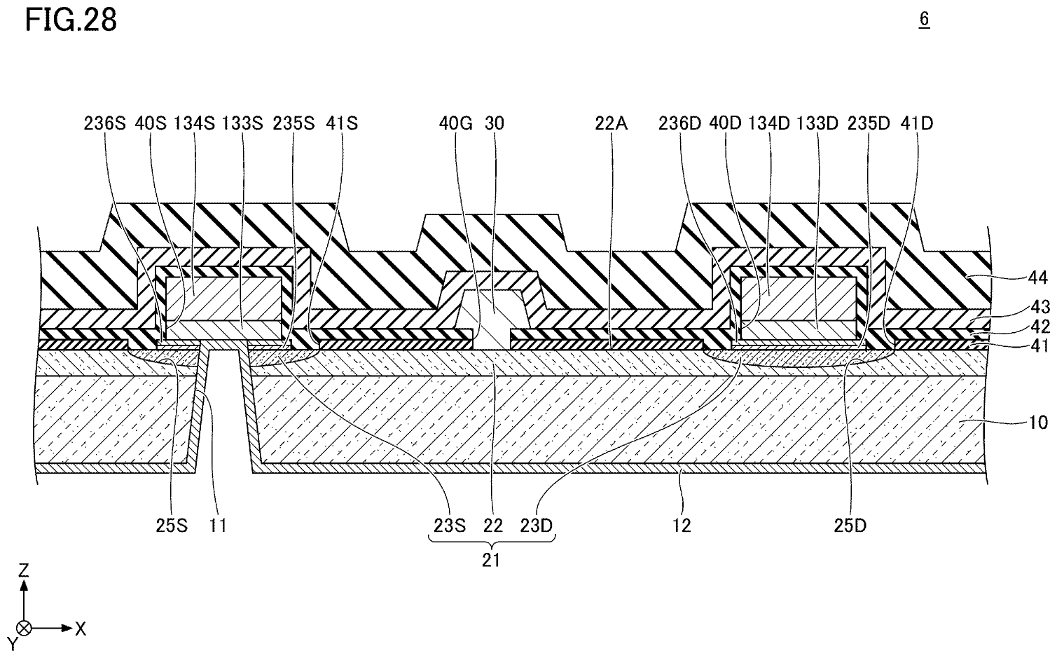

A configuration of the semiconductor device according to the sixth embodiment will be described. FIG. 28 is a cross-sectional diagram of a semiconductor device according to the sixth embodiment.

As illustrated in FIG. 28, a semiconductor device 6 according to the sixth embodiment does not include the source electrode 131S and the drain electrode 131D. The adhesion layer 235S is in direct contact with the semiconductor layer 23S, and the adhesion layer 235D is in direct contact with the semiconductor layer 23D. The laminate of the adhesion layer 235S and the catalytic layer 236S is provided on the semiconductor layer 23S in the opening 41S in a plan view. The laminate of the adhesion layer 235D and the catalytic layer 236D is provided on the semiconductor layer 23D in the opening 41D in a plan view. The etching stopper 133S and the source wire 134S are provided on the catalytic layer 236S, and the etching stopper 133D and the drain wire 134D are provided on the catalytic layer 236D. The adhesion layer 235S adheres the catalytic layer 236S to the semiconductor layer 23S, and the adhesion layer 235D adheres the catalytic layer 236D to the semiconductor layer 23D. The openings 40S and 40D are not formed. The adhesion layer 235S and the catalytic layer 236S make an Ohmic contact with the semiconductor layer 23S, and the adhesion layer 235D and the catalytic layer 236D make an Ohmic contact with the semiconductor layer 23D. In the sixth embodiment, the laminate of the adhesion layer 235S and the catalytic layer 236S is an example of the first metal layer.

The insulating film 42 covers the insulating film 41, the semiconductor layer 23S, the semiconductor layer 23D, the adhesion layer 235S, the adhesion layer 235D, the catalytic layer 236S, the catalytic layer 236D, the etching stopper 133S, the etching stopper 133D, the source wire 134S, and the drain wire 134D. The insulating film 43 covers the gate electrode 30 and the insulating film 42. The insulating film 44 covers the insulating film 43.

Although not illustrated, an opening reaching the drain pad 32 is formed in the insulating films 42, 43, and 44.

The other configuration of the sixth embodiment is the same as in the third embodiment.

### [Production Method for Semiconductor Device]

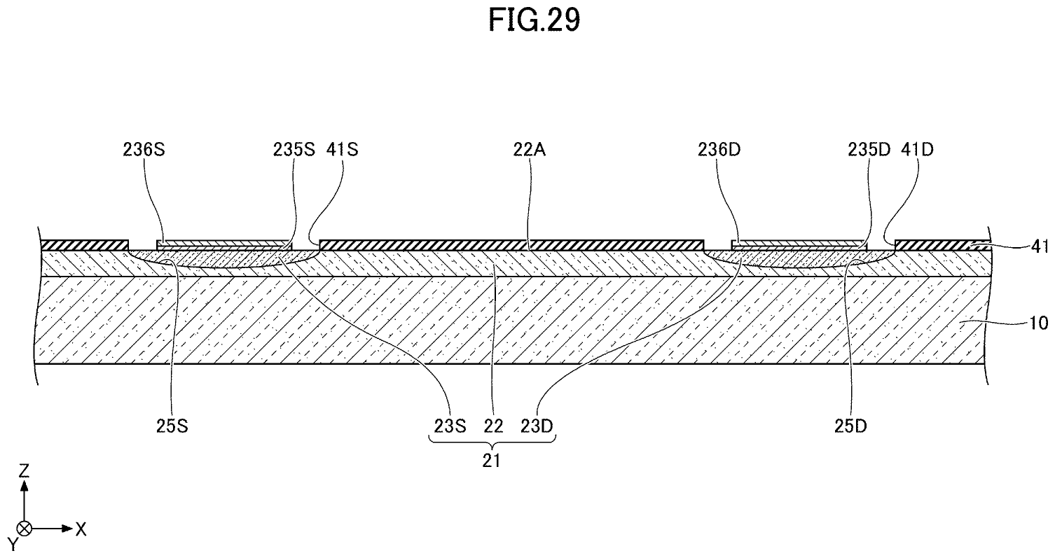

Next, a production method for a semiconductor device 6 according to the sixth embodiment will be described. FIG. 29 to FIG. 33 are cross-sectional diagrams illustrating the production method for the semiconductor device 6 according to the sixth embodiment.

First, like in the first embodiment, a process to the formation of the semiconductor layers 23S and 23D is performed (see FIG. 4). Next, as illustrated in FIG. 29, the laminate of the adhesion layer 235S and the catalytic layer 236S is formed on the semiconductor layer 23S, and the laminate of the adhesion layer 235D and the catalytic layer 236D is formed on the semiconductor layer 23D.

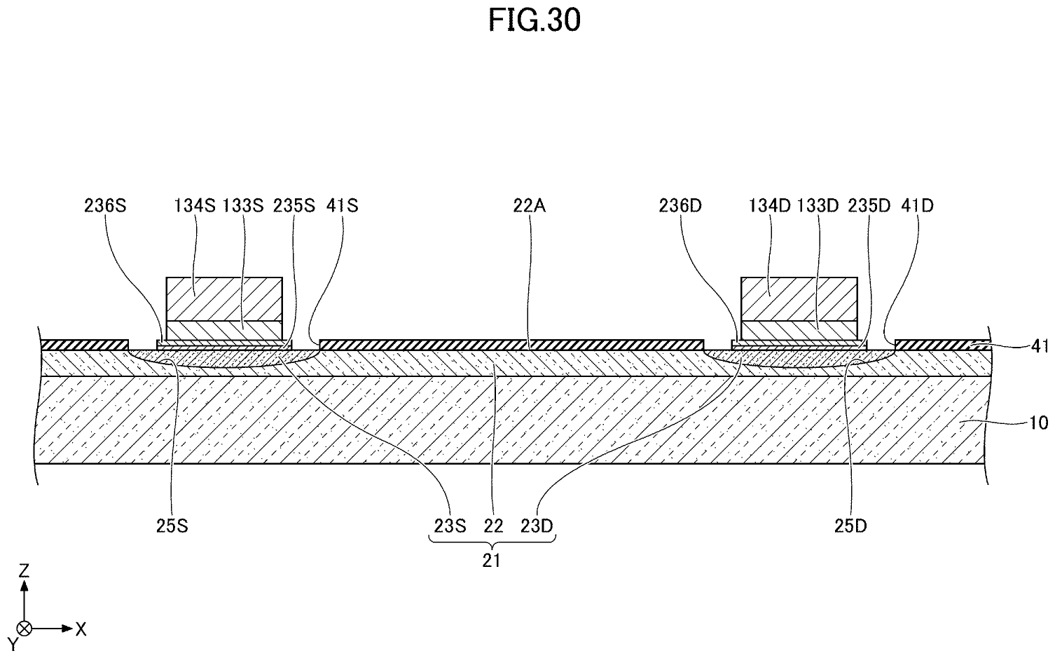

Next, as illustrated in FIG. 30, the resist pattern 102 (not illustrated) is used to form the laminate of the etching stopper 133S and the source wire 134S on the catalytic layer 236S and the laminate of the etching stopper 133D and the drain wire 134D on the catalytic layer 236D.

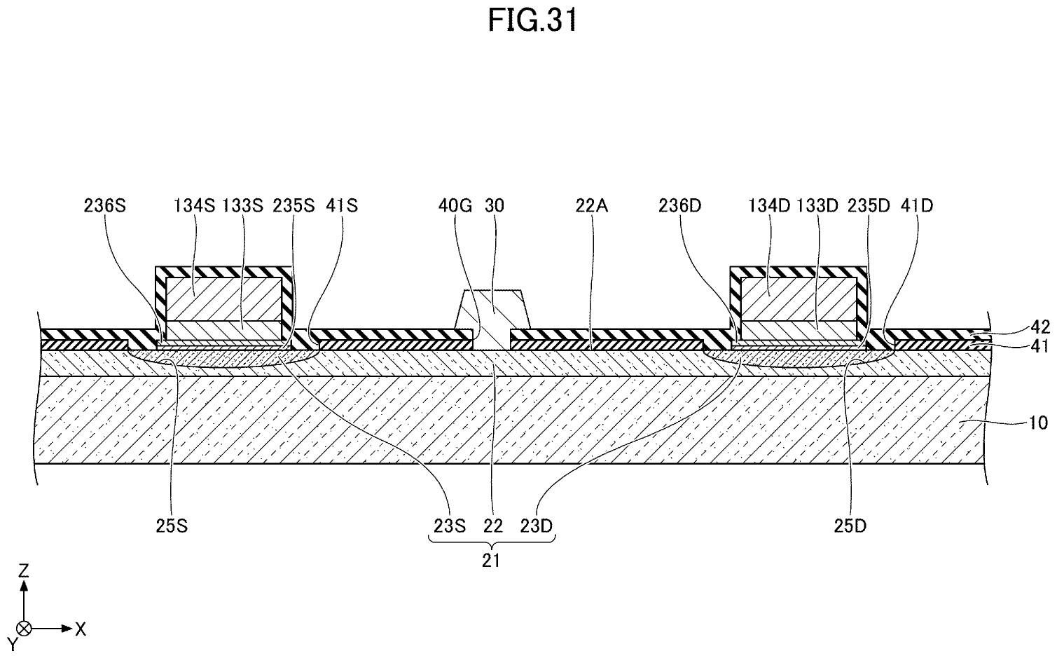

Next, as illustrated in FIG. 31, the insulating film 42 covering the insulating film 41, the b semiconductor layer 23S, the semiconductor layer 23D, the adhesion layer 235S, the adhesion layer 235D, the catalytic layer 236S, the catalytic layer 236D, the etching stopper 133S, the etching stopper 133D, the source wire 134S, and the drain wire 134D is formed. Next, the opening 40G is formed in the laminate of the insulating films 41 and 42. Next, the gate electrode 30 is formed on the insulating film 42. The gate electrode 30 makes a Schottky contact with the semiconductor layer 21 through the opening 40G.

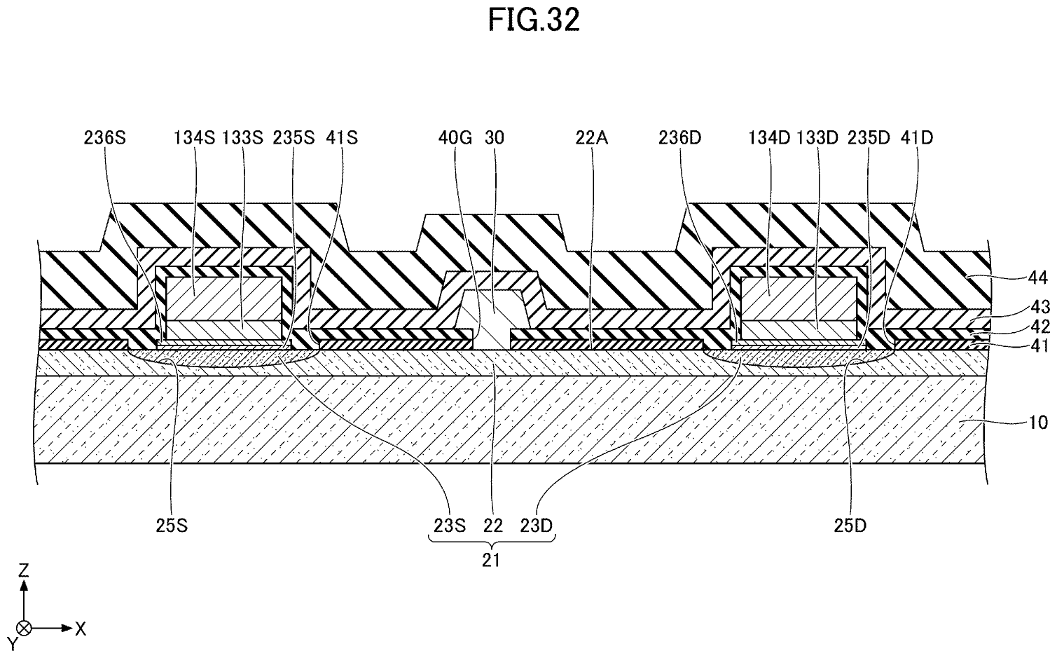

Next, as illustrated in FIG. 32, the insulating film 43 covering the gate electrode 30 and the insulating film 42 is formed. Next, the insulating film 44 covering the insulating film 43 is formed.

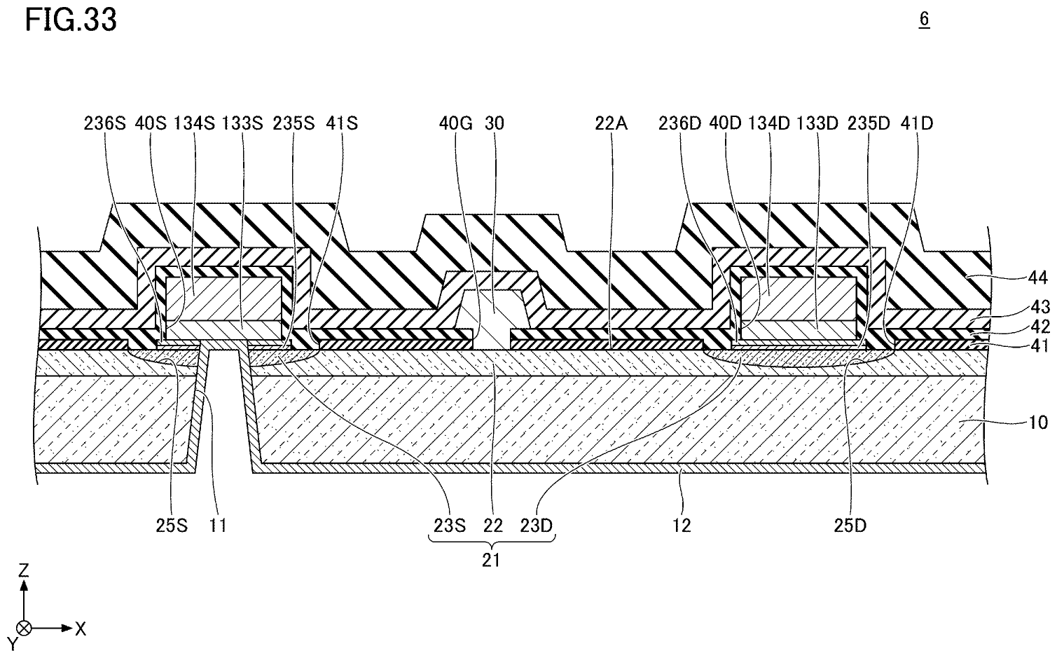

Next, as illustrated in FIG. 33, the through-hole 11 and the backside electrode 12 are formed.

In this manner, the semiconductor device 6 according to the sixth embodiment can be produced.

In the sixth embodiment, the etching stopper 133S having a large thickness can be formed while ensuring high dimensional accuracy of the laminate of the adhesion layer 235S and the catalytic layer 236S, and penetration of the through-hole 11 through the etching stopper 133S can be prevented. This readily realizes downsizing. Furthermore, there is no need to form the source electrode 131S and the drain electrode 131D, and there is no need to form the openings 40S and 40D. Thus, it is possible to reduce a lead time and increase productivity. It is also possible to make the semiconductor device thinner.

No particular limitation is imposed on the configuration of the semiconductor layer 21. For example, the electron supply layer may be above the electron transit layer, or the electron transit layer may be above the electron supply layer.

Although the embodiments of the present disclosure have been described above in detail, the present disclosure should not be construed as being limited to the described specific embodiments. Various modifications and changes are possible within a scope of matters recited in claims.

What is claimed is:

1. A semiconductor device, comprising:
a substrate;
a first nitride semiconductor layer on the substrate;
a first metal layer on the first nitride semiconductor layer;
a second metal layer on the first metal layer;
a third metal layer on the second metal layer; and
a fourth metal layer, wherein
the substrate, the first nitride semiconductor layer, and the first metal layer have a through-hole that penetrates the substrate, the first nitride semiconductor layer, and the first metal layer and to which the second metal layer is exposed,
the first metal layer makes an Ohmic contact with the first nitride semiconductor layer,
resistance of the second metal layer to etching using a reactive gas is higher than resistance of the first metal layer to etching using the reactive gas,
resistivity of the third metal layer is lower than resistivity of the first metal layer and resistivity of the second metal layer, and
the fourth metal layer is on an inner surface of the through-hole and is in direct contact with the second metal layer.

2. The semiconductor device according to claim 1, wherein
the reactive gas includes chlorine or fluorine.

3. The semiconductor device according to claim 1, wherein
the substrate is a silicon carbide substrate.

4. The semiconductor device according to claim 1, wherein
the first nitride semiconductor layer includes
a second nitride semiconductor layer including a recess in a surface of the second nitride semiconductor layer, the surface facing the first metal layer, and
a third nitride semiconductor layer in the recess, the third nitride semiconductor layer having a carrier density higher than a carrier density of the second nitride semiconductor layer, and
the first metal layer makes an Ohmic contact with the third nitride semiconductor layer.

5. The semiconductor device according to claim 1, wherein
the second metal layer includes a nickel layer exposed to the through-hole.

6. The semiconductor device according to claim 5, wherein
the nickel layer is an electrolytic nickel plating layer, and
the semiconductor device further includes a plating base layer between the first metal layer and the electrolytic nickel plating layer.

7. The semiconductor device according to claim 5, wherein
the nickel layer is an electroless nickel plating layer, and
the semiconductor device further includes
a catalytic layer between the first metal layer and the electroless nickel plating layer, and
an adhesion layer between the first metal layer and the catalytic layer and in direct contact with the first metal layer and the catalytic layer.

8. The semiconductor device according to claim 1, wherein
the first metal layer includes a titanium layer, a tantalum layer, a gold layer, or an aluminum layer, the titanium layer, the tantalum layer, the gold layer, or the aluminum layer being in direct contact with the first nitride semiconductor layer.

9. The semiconductor device according to claim 4, wherein
the second metal layer includes an electroless nickel plating layer exposed to the through-hole, and
the first metal layer includes
a catalytic layer between the third nitride semiconductor layer and the electroless nickel plating layer, and
an adhesion layer between the third nitride semiconductor layer and the catalytic layer and in direct contact with the third nitride semiconductor layer and the catalytic layer.

10. A semiconductor device, comprising:
a silicon carbide substrate;
a first nitride semiconductor layer on the silicon carbide substrate;
a first metal layer on the first nitride b semiconductor layer, the first metal layer including a titanium layer, a tantalum layer, a gold layer, or an aluminum layer;
a nickel plating layer on the first metal layer;
a first gold layer on the nickel plating layer; and
a second gold layer, wherein
the first nitride semiconductor layer includes
a second nitride semiconductor layer including a recess in a surface of the second nitride semiconductor layer, the surface facing the first metal layer, and
a third nitride semiconductor layer in the recess, the third nitride semiconductor layer having a carrier density higher than a carrier density of the second nitride semiconductor layer,
the silicon carbide substrate, the first nitride semiconductor layer, and the first metal layer have a through-hole that penetrates the silicon carbide substrate, the first nitride semiconductor layer, and the first metal layer and to which the nickel plating layer is exposed,
the first metal layer makes an Ohmic contact with the third nitride semiconductor layer, and
the second gold layer is on an inner surface of the through-hole and in direct contact with the nickel plating layer.

11. A production method for a semiconductor device, the production method comprising:
forming a first nitride semiconductor layer on a substrate;
forming a first metal layer on the first nitride semiconductor layer, the first metal layer making an Ohmic contact with the first nitride semiconductor layer;
forming a second metal layer on the first metal layer, resistance of the second metal layer to etching using a reactive gas being higher than resistance of the first metal layer to etching using the reactive gas;
forming a third metal layer on the second metal layer, resistivity of the third metal layer being lower than resistivity of the first metal layer and the second metal layer;
forming a through-hole through the substrate, the first nitride semiconductor layer, and the first metal layer by etching using the reactive gas, where the through-hole penetrates the substrate, the first nitride semiconductor layer, and the first metal layer, and the second metal layer is exposed to the through-hole; and
forming a fourth metal layer on an inner surface of the through-hole, the fourth metal layer being in direct contact with the second metal layer.
